(19) United States
(12) Patent Application Publication
(10) Pub. No.: US 2026/0033063 A1
(43) Pub. Date: Jan. 29, 2026

(54) MICRO LIGHT-EMITTING DISPLAY APPARATUS AND METHOD OF MANUFACTURING THE SAME

(71) Applicant: SAMSUNG ELECTRONICS CO., LTD., Suwon-si (KR)

(72) Inventors: Kiho KONG, Suwon-si (KR); Junhee CHOI, Suwon-si (KR); Sunil KIM, Suwon-si (KR); Jangwoo YOU, Suwon-si (KR)

(73) Assignee: SAMSUNG ELECTRONICS CO., LTD., Suwon-si (KR)

(21) Appl. No.: 19/025,120

(22) Filed: Jan. 16, 2025

(30) Foreign Application Priority Data
Jul. 25, 2024 (KR) 10-2024-0098920

(51) Int. Cl. H10H 29/39; H10H 29/01; H10H 29/14

(52) U.S. Cl. CPC H10H 29/39; H10H 29/012; H10H 29/032; H10H 29/142

(57) ABSTRACT

A micro light-emitting display apparatus and a method of manufacturing the same are provided. The micro light-emitting display apparatus may include a plurality of light-emitting stack structures spaced apart from each other on a backplane substrate, the plurality of light-emitting stack structures may have different heights from each other and may be configured to emit light of different wavelengths, and light may only be emitted from a light-emitting unit located on an upper portion of each of the plurality of light-emitting stack structures.

### CROSS-REFERENCE TO RELATED APPLICATION

This application is based on and claims priority under 35 U.S.C. § 119 to Korean Patent Application No. 10-2024-0098920, filed on Jul. 25, 2024, in the Korean Intellectual Property Office, the disclosure of which is incorporated by reference herein in its entirety.

### BACKGROUND

### 1. Field

The disclosure relates to a micro light-emitting display apparatus and a method of manufacturing the same.

### 2. Description of the Related Art

Liquid crystal displays (LCDs) and organic light-emitting diode (OLED) displays are widely used as display apparatuses. In addition, technology for manufacturing high-resolution display apparatuses using micro LEDs has recently been in the spotlight. LEDs have advantages of low power consumption and being eco-friendly. Because of these advantages, industrial demand for LEDs is increasing.

LED displays that directly use micro LEDs as pixels are being developed and commercialized.

LED display pixels may be designed in various ways, and recently, various technologies to vertically stack micro LEDs (R-LEDs) that emit red light, micro LEDs (G-LEDs) that emit green light, and micro LEDs (B-LEDs) that emit blue light have been introduced. However, satisfactory results have not been achieved in terms of efficiency or bonding for vertically stacking micro LEDs.

### SUMMARY

Provided is a micro light-emitting display apparatus.

Further, provided is a method of manufacturing a micro light-emitting display apparatus.

Additional aspects will be set forth in part in the description which follows and, in part, will be apparent from the description, or may be learned by practice of the presented embodiments of the disclosure.

According to an aspect of the disclosure, a micro light-emitting display apparatus includes: a backplane substrate comprising at least one driving element; a first light-emitting stack structure on the backplane substrate; and a second light-emitting stack structure on the backplane substrate and spaced apart from the first light-emitting stack structure, wherein the first light-emitting stack structure comprises a first light-emitting unit comprising a first electrode, a first semiconductor layer, a first active layer configured to emit light of a first wavelength, a second semiconductor layer, and a second electrode, which are stacked in order, wherein the second light-emitting stack structure comprises a first dummy stack unit and a second light-emitting unit, and a height of the first dummy stack unit and a height of the first light-emitting unit are at a same level, wherein the second light-emitting unit comprises a third electrode, a third semiconductor layer, a second active layer configured to emit light of a second wavelength different from the first wavelength, a fourth semiconductor layer, and a fourth electrode, which are stacked in order on an upper portion of the first dummy stack unit in a direction perpendicular to the backplane substrate, wherein the first electrode has a width greater than a width of the first semiconductor layer, comprises a first exposed surface exposed from the first semiconductor layer, and is connected to the at least one driving element, and wherein the third electrode has a width that is greater than a width of the third semiconductor layer, comprises a second exposed surface exposed from the third semiconductor layer, and is connected to the at least one driving element.

The first dummy stack unit may have a width that is greater than a width of the second active layer of the second light-emitting unit.

The first dummy stack unit may have a width that is the same as a width of a third electrode layer.

At a same height, the first dummy stack unit may include a material layer that is the same as a material layer of the first light-emitting unit.

The first dummy stack unit may be configured to receive no voltage.

The micro light-emitting display apparatus may further include a third light-emitting stack structure spaced apart from the second light-emitting stack structure, wherein the third light-emitting stack structure includes: a second dummy stack unit having a height that is the same level as the height of the first light-emitting unit; a third dummy stack unit on an upper portion of the second dummy stack unit having a height that is at a same level as a height of the second light-emitting unit; and a third light-emitting unit, wherein the third light-emitting unit includes a fifth electrode, a fifth semiconductor layer, a third active layer configured to emit light of a third wavelength different from the first wavelength and the second wavelength, a sixth semiconductor layer, and a sixth electrode, which are stacked in order on an upper portion of the third dummy stack unit in the direction perpendicular to the backplane substrate, and wherein the fifth electrode has a width that is greater than a width of the fifth semiconductor layer, includes a third exposed surface exposed from the fifth semiconductor layer, and is connected to the at least one driving element.

The second dummy stack unit and the third dummy stack unit may be configured to receive no voltage.

The micro light-emitting display apparatus may further include: a first conductive layer configured to electrically connect the at least one driving element to the first exposed surface and the second exposed surface.

Each of the first light-emitting unit and the second light-emitting unit may have an uneven structure.

The micro light-emitting display apparatus may further include a first lens on an upper portion of the first light-emitting unit and a second lens on an upper portion of the second light-emitting unit.

The micro light-emitting display apparatus may further include: a planarization layer on the first light-emitting stack structure and the second light-emitting stack structure, wherein the planarization layer includes a first hole that exposes the first light-emitting unit; a first lens within the first hole, wherein an upper portion of the first lens includes a convex shape; and a second lens on an upper portion of the second light-emitting unit.

The micro light-emitting display apparatus may further include a bonding layer between the backplane substrate and the first light-emitting stack structure and between the backplane substrate and the second light-emitting stack structure.

The bonding layer may have a thickness in a range of 0.3 μm to 5 μm.

The micro light-emitting display apparatus may further include a bonding layer between the first dummy stack unit and the second light-emitting unit.

According to aspect of the disclosure, a method of manufacturing a micro light-emitting display apparatus, includes: forming a first epitaxial structure by stacking in order a second semiconductor layer, a first active layer, a first semiconductor layer, and a first electrode on a first epitaxial substrate; forming a backplane substrate including at least one driving element; coupling the first epitaxial structure to the backplane substrate; removing the first epitaxial substrate from the first epitaxial structure; forming a second electrode in the first epitaxial structure; forming a second epitaxial structure by stacking in order a fourth semiconductor layer, a second active layer, a third semiconductor layer, and a third electrode on a second epitaxial substrate; coupling the second epitaxial structure to the second electrode; forming a fourth electrode in the second epitaxial structure; forming a second light-emitting unit by etching the second epitaxial structure; forming a first dummy stack unit on a lower portion of the second light-emitting unit by etching the first epitaxial structure, and forming a first light-emitting unit that is spaced apart from the first dummy stack unit and having a height that is at a same level as a height of the first dummy stack unit.

The first dummy stack unit may have a width that is greater than a width of the second active layer of the second light-emitting unit.

The first dummy stack unit may have a width that is the same as a width of a third electrode layer of the micro light-emitting display apparatus.

The method may further include forming a charge blocking layer on the first dummy stack unit, the second light-emitting unit, and the first light-emitting unit, wherein the forming the charge blocking layer includes patterning the charge blocking layer such that a partial surface of the third electrode, an upper surface of the fourth electrode, a partial surface of the first electrode, and an upper surface of the second electrode are exposed from the charge blocking layer.

The coupling the first epitaxial structure to the backplane substrate may include coupling the first epitaxial structure to the backplane substrate by a first bonding layer.

The method further includes: forming, after forming the fourth electrode, a third epitaxial structure by stacking in order a sixth semiconductor layer, a third active layer, a fifth semiconductor layer, and a fifth electrode on a third epitaxial substrate; coupling the third epitaxial structure to the fourth electrode; and forming a sixth electrode on the third epitaxial structure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a micro light-emitting display apparatus according to an embodiment;

FIG. 2A illustrates an embodiment in which the micro light-emitting display apparatus shown in FIG. 1 further includes a third light-emitting stack structure;

FIG. 2B schematically illustrates an electrode connection structure of FIG. 2A;

FIG. 3A illustrates an embodiment in which the micro light-emitting display apparatus shown in FIG. 2A further includes a charge blocking layer and a conductive layer;

FIG. 3B schematically illustrates an electrode connection structure of FIG. 3A;

FIG. 4 illustrates an embodiment in which the micro light-emitting display apparatus shown in FIG. 3A further includes an uneven structure;

FIG. 5 illustrates an embodiment in which the micro light-emitting display apparatus shown in FIG. 2A further includes lenses;

FIG. 6 illustrates an embodiment in which the micro light-emitting display apparatus shown in FIG. 4 further includes lenses;

FIG. 7 schematically illustrates a display apparatus having a red, green, and blue pixel structure;

FIG. 8 schematically illustrates a display apparatus having a green and red pixel structure and a green and blue pixel structure;

FIGS. 9A to 9M are diagrams illustrating a method of manufacturing a micro light-emitting display apparatus according to an embodiment;

FIGS. 10A and 10B are diagrams illustrating a method of forming an uneven structure in a micro light-emitting display apparatus according to an embodiment;

FIG. 11 is a schematic block diagram of an electronic device according to an embodiment;

FIG. 12 illustrates an example in which a micro light-emitting display apparatus is applied to a mobile device according to an embodiment;

FIG. 13 illustrates an example in which a micro light-emitting display apparatus is applied to a vehicle display apparatus according to an embodiment;

FIG. 14 illustrates an example in which a micro light-emitting display apparatus is applied to augmented reality (AR) glasses according to an embodiment;

FIG. 15 illustrates an example in which a micro light-emitting display apparatus is applied to a signage according to an embodiment; and

FIG. 16 illustrates an example in which a micro light-emitting display apparatus is applied to a wearable display according to an embodiment.

### DETAILED DESCRIPTION

Reference will now be made in detail to non-limiting example embodiments with reference to the accompanying drawings, wherein like reference numerals refer to like elements throughout. In this regard, embodiments of the present disclosure may have different forms and should not be construed as being limited to the descriptions set forth herein. Accordingly, the example embodiments are merely described below, by referring to the figures, to explain example aspects. As used herein, the term “and/or” includes any and all combinations of one or more of the associated listed items. Expressions such as “at least one of,” when preceding a list of elements, modify the entire list of elements and do not modify the individual elements of the list.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, a micro light-emitting display apparatus and a method of manufacturing the same according to various embodiments are described in detail with reference to the accompanying drawings. In the drawings, like reference numerals in the drawings denote like elements, and sizes of components in the drawings may be exaggerated for clarity and convenience of explanation. While terms such as “first,” “second,” etc., may be used to describe various components, such components are not be limited to the above terms. The above terms are used only to distinguish one component from another.

An expression used in the singular encompasses the expression of the plural, unless it has a clearly different meaning in the context. When a portion “includes” an element, another element may be further included, rather than excluding the existence of the other element, unless otherwise described. Sizes or thicknesses of components in the drawings may be arbitrarily exaggerated for convenience of explanation. Further, when a certain material layer is described as being disposed on a substrate or another layer, the material layer may be in contact with the other layer, or there may be a third layer between the material layer and the other layer. In the following embodiments, materials constituting each layer are provided merely as an example, and other materials may also be used.

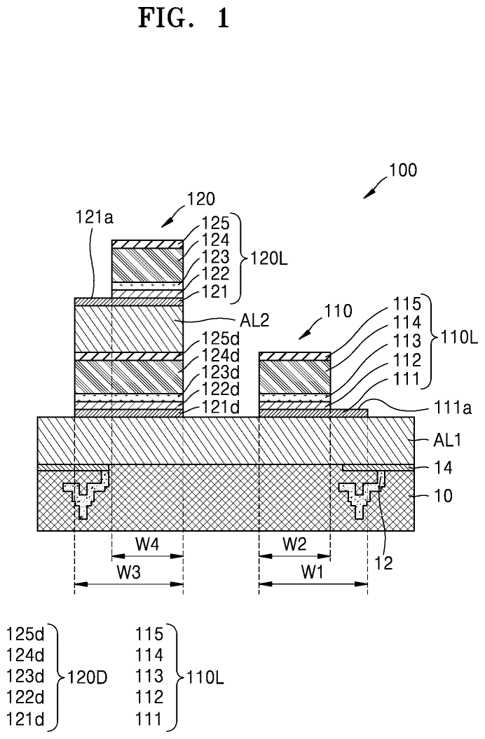

FIG. 1 is a cross-sectional view of a micro light-emitting display apparatus 100 according to an embodiment.

The micro light-emitting display apparatus 100 may include a backplane substrate 10 including at least one driving element 12, and a first light-emitting stack structure 110 and a second light-emitting stack structure 120 provided to be spaced apart from each other on the backplane substrate 10. The at least one driving element 12 may be for electrically driving the first light-emitting stack structure 110 and the second light-emitting stack structure 120, and may include, for example, a transistor, a thin film transistor, or a high electron mobility transistor (HEMT). However, the driving element 12 is not limited thereto, and may further include a resistor, a capacitor, etc.

The backplane substrate 10 may include electrode pads 14 spaced apart from each other, and the electrode pad 14 may be prepared for ground or connected to one of a plurality of driving elements 12 included in the backplane substrate 10. For example, the electrode pad 14 may be connected to the driving element 12n such as, for example, a drain of a transistor, provided on the backplane substrate 10 for driving the first light-emitting stack structure 110 and the second light-emitting stack structure 120.

A first bonding layer AL1 may be between the first light-emitting stack structure 110 and the backplane substrate 10 and between the second light-emitting stack structure 120 and the backplane substrate 10. The first bonding layer AL1 may have a thickness in the range of 0.3 μm to 5 μm. Alternatively, the first bonding layer AL1 may have the thickness in the range of 0.2 μm to 4 μm.

The first bonding layer AL1 may be for coupling an epitaxial structure to be described below to the backplane substrate 10, and may include, for example, an adhesive layer or a direct bonding layer. The adhesive layer may include, for example, epoxy, polyimide (PI), benzocyclobutene (BCB), etc. The direct bonding layer may be formed by, for example, plasma or ion beam treatment. The first bonding layer AL1 may be for physically coupling the epitaxial structure to the backplane substrate 10, and the epitaxial structure may be coupled to the backplane substrate 10 in a simple method that requires no electrical connection. However, the first bonding layer AL1 is not limited thereto.

The first light-emitting stack structure 110 may include a first electrode 111, a first semiconductor layer 112, a first active layer 113 that emits light of a first wavelength, a second semiconductor layer 114, and a second electrode 115, which are stacked in order. The first electrode 111, the first semiconductor layer 112, the first active layer 113, the second semiconductor layer 114, and the second electrode 115 may constitute a first light-emitting unit 110L.

The first semiconductor layer 112 may include a first type semiconductor. For example, the first semiconductor layer 112 may include a p-type semiconductor. Alternatively, the first semiconductor layer 112 may include an n-type semiconductor. The first semiconductor layer 112 may include a Group III-V based p-type semiconductor such as, for example, p-GaN, p-InGaN, p-AlInGaN, or p-AlGaInP. The first semiconductor layer 112 may have a single-layer structure or a multi-layer structure.

The first active layer 113 may be provided on an upper surface of the first semiconductor layer 112. The first active layer 113 may generate light by coupling electrons and holes. The first active layer 113 may include a material that emits light of the first wavelength such as, for example, red light. However, the first active layer 113 is not limited thereto. The first active layer 113 may have a multi-quantum well (MQW) structure or a single-quantum well (SQW) structure. The first active layer 113 may include a Group III-V semiconductor such as, for example, GaN, InGaN, AlInGaN, or AlGaInP.

The second semiconductor layer 114 may be provided on an upper surface of the first active layer 113. The second semiconductor layer 114 may include, for example, an n-type semiconductor. Alternatively, the second semiconductor layer 114 may include a p-type semiconductor. The second semiconductor layer 114 may include a Group III-V based n-type semiconductor such as, for example, n-GaN, n-InGaN, n-AlInGaN, or n-AlGaInP. The second semiconductor layer 114 may have a single-layer structure or a multi-layer structure.

A width W1 of the first electrode 111 may be greater than a width W2 of the first semiconductor layer 112. In addition, the first electrode 111 may include a first exposed surface 111a exposed from the first semiconductor layer 112. The first exposed surface 111a may be electrically connected to the at least one driving element 12. The first exposed surface 111a and the at least one driving element 12 may be connected to each other directly or through another medium. The first exposed surface 111a may be provided not only on one side of the first electrode 111 but also on both sides of the first electrode 111. The first semiconductor layer 112, the first active layer 113, the second semiconductor layer 114, and the second electrode 115 may have substantially the same width as each other.

The first light-emitting unit 110L may have a structure in which the first active layer 113 is activated by applying voltage to the first electrode 111 and the second electrode 115.

The first electrode 111 may include a reflective material to reflect light emitted from the first active layer 113 downward. The first electrode 111 may include, for example, Ag, Au, Al, Cr, or Ni, or an alloy thereof. However, the first electrode 111 is not limited thereto. The second electrode 115 may be formed as a transparent electrode such that the light emitted from the first active layer 113 may pass through the second electrode 115. The second electrode 115 may include, for example, indium tin oxide (ITO), ZnO, indium zinc oxide (IZO), IGZO, etc. However, the second electrode 115 is not limited thereto.

The second light-emitting stack structure 120 may include a first dummy stack unit 120D at a same height as a height of the first light-emitting unit 110L, and a second light-emitting unit 120L on an upper portion of the first dummy stack unit 120D.

The first dummy stack unit 120D may include a first dummy electrode 121d, a first dummy semiconductor layer 122d, a first dummy active layer 123d, a second dummy semiconductor layer 124d, and a second dummy electrode 125d. The first dummy stack unit 120D may have a structure having a constant width overall. In other words, the first dummy electrode 121d, the first dummy semiconductor layer 122d, the first dummy active layer 123d, the second dummy semiconductor layer 124d, and the second dummy electrode 125d may have the same width as each other. Here, the same width may be slightly different in a manufacturing process, but may be understood as a case of being etched by using one etching mask in the manufacturing process to be described below.

The first dummy electrode 121d may include the same material at the same height as the first electrode 111 with respect to the backplane substrate 10. The first dummy semiconductor layer 122d, the first dummy active layer 123d, the second dummy semiconductor layer 124d, and the second dummy electrode 125d may include the same materials at the same heights as the first semiconductor layer 112, the first active layer 113, the second semiconductor layer 114, and the second electrode 115, respectively. The first dummy stack unit 120D may include an electrode but may have a deactivated structure by preventing voltage from being applied to the electrode.

The second light-emitting unit 120L may include a third electrode 121, a third semiconductor layer 122, a second active layer 123 that emits light of a second wavelength, a fourth semiconductor layer 124, and a fourth electrode 125, which are stacked in order in a direction perpendicular to the backplane substrate 10. The second light-emitting unit 120L may be at a different height than a height of the first light-emitting unit 110L. Herein, “in order” refers to the order of layers and does not limit the intervention of other layers between the layers.

A second bonding layer AL2 may be between the first dummy stack unit 120D and the second light-emitting unit 120L. The second bonding layer AL2 may include a same material as a material of the first bonding layer AL1. The second bonding layer AL2 may have a thickness in the range of 0.3 μm to 5 μm. Alternatively, the second bonding layer AL2 may have the thickness in the range of 0.2 μm to 4 μm.

The third semiconductor layer 122 may include a first type semiconductor. For example, the third semiconductor layer 122 may include a p-type semiconductor. Alternatively, the third semiconductor layer 122 may include an n-type semiconductor. The third semiconductor layer 122 may include a Group III-V based p-type semiconductor such as, for example, p-GaN, p-InGaN, p-AlInGaN, or p-AlGaInP. The third semiconductor layer 122 may have a single-layer structure or a multi-layer structure. The third semiconductor layer 122 may include the same material as a material of the first semiconductor layer 112. Alternatively, the third semiconductor layer 122 may include a material different from a material of the first semiconductor layer 112.

The second active layer 123 may be provided on an upper surface of the third semiconductor layer 122. The second active layer 123 may generate light of the second wavelength, and the second wavelength may be different from the first wavelength. The second wavelength light may have, for example, a green light wavelength. However, embodiments of the present disclosure are not limited thereto.

The second active layer 123 may have an MQW structure or an SQW structure. The second active layer 123 may include a Group III-V semiconductor such as, for example, GaN, InGaN, AlInGaN, or AlGaInP. The second active layer 123 may include a material different from a material of the first active layer 113. Here, the different material may include not only cases in which constituent elements are different, but also cases in which constituent elements are the same and composition ratios are different.

The fourth semiconductor layer 124 may be provided on an upper surface of the second active layer 123. The fourth semiconductor layer 124 may include, for example, an n-type semiconductor. Alternatively, the fourth semiconductor layer 124 may include a p-type semiconductor. The fourth semiconductor layer 124 may include a Group III-V n-type semiconductor such as, for example, n-GaN, n-InGaN, n-AlInGaN, or n-AlGaInP. The fourth semiconductor layer 124 may have a single-layer structure or a multi-layer structure.

A width W3 of the third electrode 121 may be greater than a width W4 of the third semiconductor layer 122. In addition, the third electrode 121 may include a second exposed surface 121a exposed from the third semiconductor layer 122. The second exposed surface 121a may be electrically connected to the at least one driving element 12. The second exposed surface 121a and the at least one driving element 12 may be connected to each other through another medium. The second exposed surface 121a may be provided not only on one side of the third electrode 121 but also on both sides of the third electrode 121. The third semiconductor layer 122, the second active layer 123, the fourth semiconductor layer 124, and the fourth electrode 125 may have the same width as each other. In addition, the width W3 of the third electrode 121 may be the same as the width of the first dummy stack unit 120D.

The second light-emitting unit 120L may have a structure in which the second active layer 123 is activated by applying a voltage to the third electrode 121 and the fourth electrode 125.

The micro light-emitting display apparatus 100 may have a vertical stack structure, and the first light-emitting unit 110L and the second light-emitting unit 120L that emit light of different wavelengths may be at different heights with respect to the backplane substrate 10. The micro light-emitting display apparatus 100 may not need to have a color conversion member that is excited by, for example, blue light and converts the blue light into light of another wavelength in order to implement a color image. In addition, the micro light-emitting display apparatus 100 may emit light of different colors in the first light-emitting unit 110L and the second light-emitting unit 120L, thereby displaying a color image without a color filter. In addition, the micro light-emitting display apparatus 100 may emit corresponding color light only in the first light-emitting unit 110L and the second light-emitting unit 120L on the uppermost portions of the first light-emitting stack structure 110 and the second light-emitting unit 120L, respectively, thereby effectively securing a light-emitting area. The first light-emitting stack structure 110 and the second light-emitting stack structure 120 may each have a micro-size width. Here, the width may represent the width of each of the first light-emitting unit 110L and the second light-emitting unit 120L. For example, the second width W2 of the first light-emitting unit 110L and the fourth width W4 of the second light-emitting unit 120L may range from 0.1 μm to 100 μm. Alternatively, the second width W2 of the first light-emitting unit 110L and the fourth width W4 of the second light-emitting unit 120L may be in the range of 0.1 μm to 50 μm.

The micro light-emitting display apparatus 100 may be applied to, for example, a pentile pixel structure. The pentile pixel structure may include neighboring pixels sharing sub-pixels. The pentile pixel structure may include one pixel including, for example, a red sub-pixel R and a green sub-pixel G, or a blue sub-pixel B and a green sub-pixel G. However, this is only an example, and various pixel structures are possible.

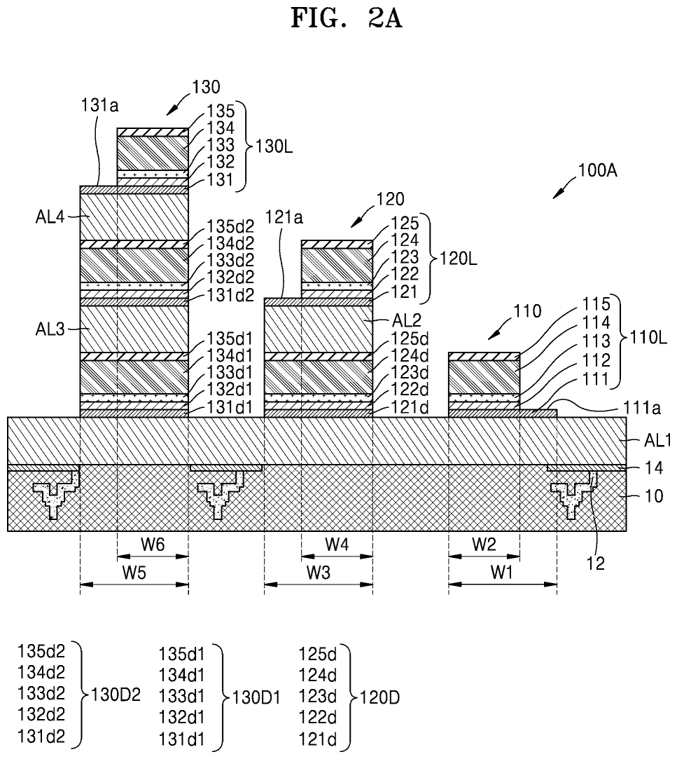

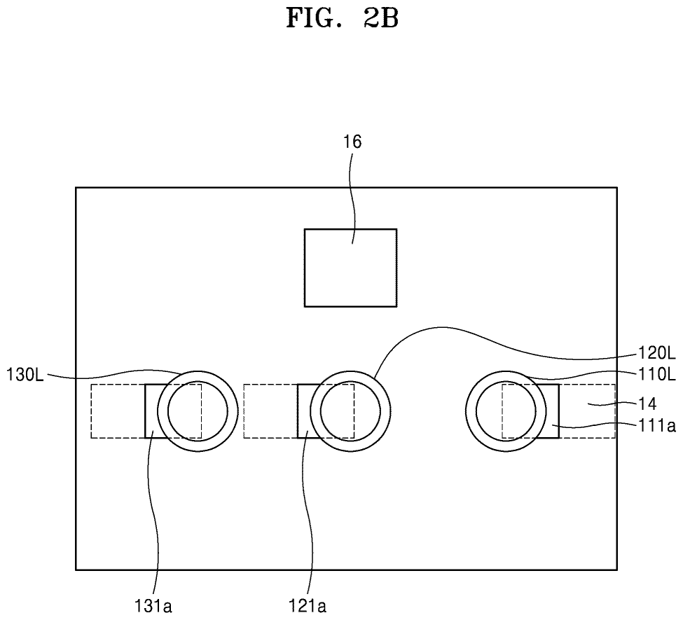

FIG. 2A illustrates an example in which a third light-emitting stack structure 130 is further included in the micro light-emitting display apparatus 100 shown in FIG. 1. In FIG. 2A, components denoted by the same reference numerals as in FIG. 1 have substantially the same configurations and functions, and thus, repeated descriptions thereof may be omitted herein.

A micro light-emitting display apparatus 100A may include the first light-emitting stack structure 110, the second light-emitting stack structure 120, and the third light-emitting stack structure 130, which are spaced apart from each other on the backplane substrate 10.

The third light-emitting stack structure 130 may include a second dummy stack unit 130D1 at the same height as a height of the first light-emitting unit 110L, a third dummy stack unit 130D2 on an upper portion of the second dummy stack unit 130D1, and a third light-emitting unit 130L on an upper portion of the third dummy stack unit 130D2. The second dummy stack unit 130D1 may be at the same height as a height of the first dummy stack unit 120D. In addition, the second dummy stack unit 130D1 may include material layers including the same material at the same height as layers included in the first dummy stack unit 120D.

The third dummy stack unit 130D2 may be at the same height as a height of the second light-emitting unit 120L. A third bonding layer AL3 may be between the second dummy stack unit 130D1 and the third dummy stack unit 130D2. In addition, a fourth bonding layer AL4 may be between the third dummy stack unit 130D2 and the third light-emitting unit 130L. The third bonding layer AL3 may include the same material and have the same thickness at the same height as the second bonding layer AL2.

The second dummy stack unit 130D1 may include a third dummy electrode 131d1, a third dummy semiconductor layer 132d1, a second dummy active layer 133d1, a fourth dummy semiconductor layer 134d1, and a fourth dummy electrode 135d1. The second dummy stack unit 130D1 may have a structure having a constant width overall. In other words, the third dummy electrode 131d1, the third dummy semiconductor layer 132d1, the second dummy active layer 133d1, the fourth dummy semiconductor layer 134d1, and the fourth dummy electrode 135d1 may have the same width as each other.

The third dummy electrode 131d1 may include the same material and have the same thickness at the same height as the first electrode 111 and the first dummy electrode 121d with respect to the backplane substrate 10. The third dummy semiconductor layer 132d1, the second dummy active layer 133d1, the fourth dummy semiconductor layer 134d1, and the fourth dummy electrode 135d1 may include the same materials and have the same thicknesses at the same heights as the first semiconductor layer 112, the first active layer 113, the second semiconductor layer 114, and the second electrode 115, respectively. The second dummy stack unit 130D1 may include an electrode but may have a deactivated structure by preventing voltage from being applied to the electrode.

The third dummy stack unit 130D2 may include a fifth dummy electrode 131d2, a fifth dummy semiconductor layer 132d2, a third dummy active layer 133d2, a sixth dummy semiconductor layer 134d2, and a sixth dummy electrode 135d2. The third dummy stack unit 130D2 may have a structure having a constant width overall. In other words, the fifth dummy electrode 131d2, the fifth dummy semiconductor layer 132d2, the third dummy active layer 133d2, the sixth dummy semiconductor layer 134d2, and the sixth dummy electrode 135d2 may have the same width as each other. In addition, the third dummy stack unit 130D2 may have the same width as a width of the second dummy stack unit 130D1. This may be understood that the second dummy stack unit 130D1 and the third dummy stack unit 130D2 are etched by using the same etching mask or etching masks having the same width in a manufacturing process. Alternatively, a side surface of the third dummy stack unit 130D2 may be configured to be continuously connected to a side surface of the second dummy stack unit 130D1. Alternatively, the side surface of the third dummy stack unit 130D2 may be formed discontinuously with the side surface of the second dummy stack unit 130D1 such as, for example, in a stepped shape. As described above, the third dummy stack unit 130D2 may have a width different from the second dummy stack unit 130D1.

The fifth dummy electrode 131d2 may include the same material and have the same thickness at the same height as the third electrode 121 with respect to the backplane substrate 10. The fifth dummy semiconductor layer 132d2, the third dummy active layer 133d2, the sixth dummy semiconductor layer 134d2, and the sixth dummy electrode 135d2 may include the same materials and have the same thicknesses at the same heights as the third semiconductor layer 122, the second active layer 123, the fourth semiconductor layer 124, and the fourth electrode 125, respectively. The third dummy stack unit 130D2 may include an electrode but may have a deactivated structure by preventing voltage from being applied to the electrode.

The third light-emitting unit 130L may include a fifth electrode 131, a fifth semiconductor layer 132, a third active layer 133 that emits light of a third wavelength, a sixth semiconductor layer 134, and a sixth electrode 135, which are stacked in order in a direction perpendicular to the backplane substrate 10. The third light-emitting unit 130L may be at a different height than a height of the first light-emitting unit 110L, and may be at a different height than a height of the second light-emitting unit 120L. The third light-emitting unit 130L may be at a higher position than each of the first light-emitting unit 110L and the second light-emitting unit 120L.

The fourth bonding layer AL4 may be between the third dummy stack unit 130D2 and the third light-emitting unit 130L. The fourth bonding layer AL4 may include the same material as a material of the first bonding layer AL1. The fourth bonding layer AL4 may have a thickness in the range of 0.3 μm to 5 μm. Alternatively, the fourth bonding layer AL4 may have a thickness in the range of 0.2 μm to 4 μm.

The fifth semiconductor layer 132 may include a first type semiconductor. For example, the fifth semiconductor layer 132 may include a p-type semiconductor. Alternatively, the fifth semiconductor layer 132 may include an n-type semiconductor. The fifth semiconductor layer 132 may include a Group III-V based p-type semiconductor such as, for example, p-GaN, p-InGaN, p-AlInGaN, or p-AlGaInP. The fifth semiconductor layer 132 may have a single-layer structure or a multi-layer structure.

The third active layer 133 may be provided on an upper surface of the fifth semiconductor layer 132. The third active layer 133 may generate the light of the third wavelength, and the third wavelength may be different from the first wavelength and may be different from the second wavelength. The light of the third wavelength may include, for example, a blue light wavelength. However, embodiments of the present disclosure are not limited thereto.

The third active layer 133 may have an MQW structure or an SQW structure. The third active layer 133 may include a Group III-V semiconductor such as, for example, GaN, InGaN, AlInGaN, or AlGaInP. The third active layer 133 may include a material different from a material of the first active layer 113 and the second active layer 123. Here, the different material may include not only cases in which constituent elements are different, but also cases in which constituent elements are the same and composition ratios are different.

The sixth semiconductor layer 134 may be provided on an upper surface of the third active layer 133. The sixth semiconductor layer 134 may include, for example, an n-type semiconductor. Alternatively, the sixth semiconductor layer 134 may include a p-type semiconductor. The sixth semiconductor layer 134 may include a Group III-V based n-type semiconductor such as, for example, n-GaN, n-InGaN, n-AlInGaN, or n-AlGaInP. The sixth semiconductor layer 134 may have a single-layer structure or a multi-layer structure.

A width W5 of the fifth electrode 131 may be greater than a width W6 of the fifth semiconductor layer 132. In addition, the fifth electrode 131 may include a third exposed surface 131a exposed from the fifth semiconductor layer 132. The third exposed surface 131a may be electrically connected to the at least one corresponding driving element 12. The third exposed surface 131a may be connected to the at least one driving element 12 through another component. The third exposed surface 131a may be provided not only on one side of the fifth electrode 131 but also on both sides of the fifth electrode 131. The fifth semiconductor layer 132, the third active layer 133, the sixth semiconductor layer 134, and the sixth electrode 135 may have the same width as each other. In addition, the width W5 of the fifth electrode 131 may be the same as the width of the third dummy stack unit 130D2.

The third light-emitting unit 130L may have a structure in which the third active layer 133 is activated by applying voltage to the fifth electrode 131 and the sixth electrode 135. That is, when voltage is applied to the fifth electrode 131 and the sixth electrode 135, electrons and holes may be combined in the third active layer 133 to emit the light of the third wavelength.

The micro light-emitting display apparatus 100A may have a vertical stack structure, and the first light-emitting unit 110L, the second light-emitting unit 120L, and the third light-emitting unit 130L that emit light of different wavelengths may be at different heights with respect to the backplane substrate 10. The micro light-emitting display apparatus 100A may emit corresponding color light only in the first light-emitting unit 110L, the second light-emitting unit 120L, and the third light-emitting unit 130L on the uppermost portions of the first light-emitting stack structure 110, the second light-emitting stack structure 120, and the third light-emitting stack structure 130, respectively, thereby effectively securing a light-emitting area.

The first dummy stack unit 120D, the second dummy stack unit 130D1, and the third dummy stack unit 130D2 may be configured not to emit light, transfer an epitaxial structure to be described below in the manufacturing process of the micro light-emitting display apparatus 100A, and etch the epitaxial structure such that the first light-emitting unit 110L, the second light-emitting unit 120L, and the third light-emitting unit 130L may be easily manufactured. FIG. 2B illustrates a simplified electrode connection structure of the micro light-emitting display apparatus 100A. The first exposed surface 111a of the first electrode 111 of the first light-emitting unit 110L may be connected to the electrode pad 14 of the corresponding driving element 12, the second exposed surface 121a of the third electrode 121 of the second light-emitting unit 120L may be connected to the electrode pad 14 of the corresponding driving element 12, and the third exposed surface 131a of the fifth electrode 131 of the third light-emitting unit 130L may be connected to the electrode pad 14 of the corresponding driving element 12. FIGS. 2A and 2B does not show a connection structure of each of the first exposed surface 111a, the second exposed surface 121a, the third exposed surface 131a and the corresponding electrode pad 14, but each of the first exposed surface 111a, the second exposed surface 121a, the third exposed surface 131a may be electrically connected to the corresponding electrode pad 14 through another connection layer. In addition, a common electrode 16 may be provided on the backplane substrate 10, and the second electrode 115 of the first light-emitting unit 110L, the fourth electrode 125 of the second light-emitting unit 120L, and the sixth electrode 135 of the third light-emitting unit 130L may be commonly connected to the common electrode 16. This will be described below.

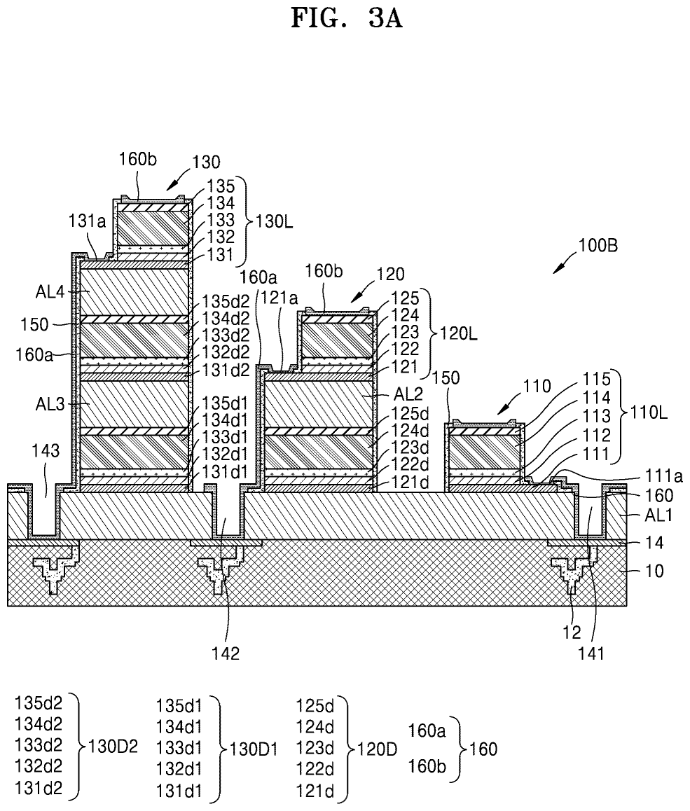

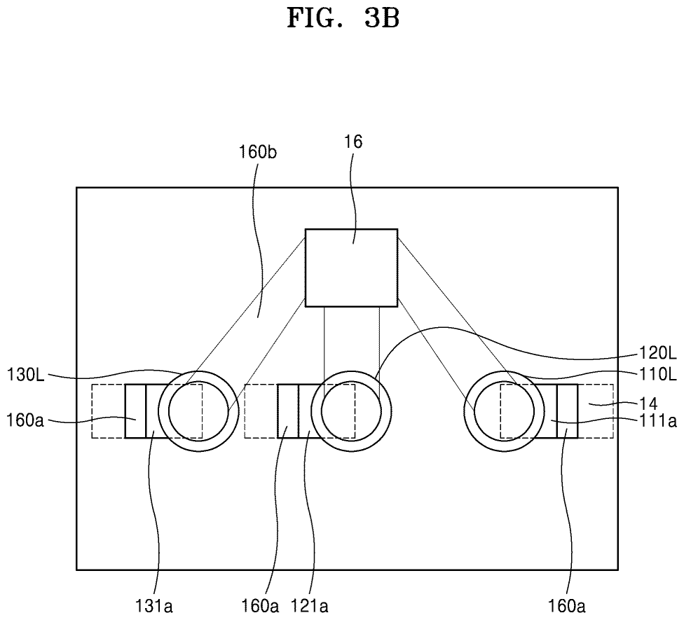

FIG. 3A illustrates that an electrode connection structure is added to the micro light-emitting display apparatus 100A shown in FIG. 2A.

A charge blocking layer 150 may be on a sidewall of the first light-emitting stack structure 110. The charge blocking layer 150 may be provided such that the first exposed surface 111a of the first electrode 111 of the first light-emitting unit 110L and an upper surface of the second electrode 115 are exposed. The charge blocking layer 150 may be in a region in which no current supply is required and block current supply. The charge blocking layer 150 may include at least one of, for example, Al₂O₃, HfO₂, AlN, or SiO₂.

In addition, the charge blocking layer 150 may be on a sidewall of the second light-emitting stack structure 120. The charge blocking layer 150 may be provided such that the second exposed surface 121a of the third electrode 121 of the second light-emitting unit 120L and an upper surface of the fourth electrode 125 are exposed. In addition, the charge blocking layer 150 may be on a sidewall of the third light-emitting stack structure 130. The charge blocking layer 150 may be provided such that the third exposed surface 131a of the fifth electrode 131 of the third light-emitting unit 130L and an upper surface of the sixth electrode 135 are exposed.

Meanwhile, a micro light-emitting display apparatus 100B may include a first groove 141, a second groove 142, and a third groove 143, which are spaced apart from each other in the first bonding layer AL1. The first groove 141, the second groove 142, and the third groove 143 may be provided such that the electrode pad 14 corresponding to each of the first groove 141, the second groove 142, and the third groove 143 is exposed.

A conductive layer 160 may be provided in each of the first light-emitting stack structure 110, the second light-emitting stack structure 120, and the third light-emitting stack structure 130. The conductive layer 160 may include a first conductive layer 160a for connecting the driving element 12 to a p-type electrode of a light-emitting unit corresponding to each, and a second conductive layer 160b for connecting a common electrode to an n-type electrode of a light-emitting unit corresponding to each. The first conductive layer 160a and the second conductive layer 160b may be separated from each other, and may serve as wirings. The conductive layer 160 may include a conductive material such as, for example, a transparent electrode material. The second conductive layer 160b may include a transparent electrode material and may be provided on an upper portion of each of the first light-emitting unit 110L, the second light-emitting unit 120L, and the third light-emitting unit 130L to transmit light emitted from each of the first light-emitting unit 110L, the second light-emitting unit 120L, and the third light-emitting unit 130L.

The first conductive layer 160a may be provided in the first groove 141 and connected to a corresponding electrode pad 14. In addition, the first conductive layer 160a may be provided along the charge blocking layer 150 and may extend to a portion of the first exposed surface 111a of the first electrode 111 that does not include the charge blocking layer 150 thereon. Accordingly, the first conductive layer 160a may connect the electrode pad 14 to the first electrode 111. Therefore, the first light-emitting unit 110L may be electrically connected to the driving element 12 through the first conductive layer 160a. The second conductive layer 160b may be provided on an upper surface of the second electrode 115 and may extend along the charge blocking layer 150 to be connected to the common electrode 16 described with reference to FIG. 2B. In addition, current supply may be blocked in a part covered by the charge blocking layer 150.

The first conductive layer 160a may be provided in the second groove 142 and connected to a corresponding electrode pad 14. In addition, the first conductive layer 160a may be provided along the charge blocking layer 150 on a side surface of the first dummy stack unit 120D, and may extend to a portion of the second exposed surface 121a of the third electrode 121 of the second light-emitting unit 120L that does not include the charge blocking layer 150 thereon. The first conductive layer 160a may connect the electrode pad 14 to the third electrode 121 of the second light-emitting unit 120L. Therefore, the second light-emitting unit 120L may be electrically connected to the driving element 12 through the first conductive layer 160a. The second conductive layer 160b may be on an upper surface of the fourth electrode 125 and may extend along the charge blocking layer 150 to be connected to the common electrode 16 described with reference to FIG. 2B. In addition, current supply may be blocked in a part covered by the charge blocking layer 150.

The first conductive layer 160a may be provided in the third groove 143 and connected to a corresponding electrode pad 14. In addition, the first conductive layer 160a may be provided along the charge blocking layer 150 on side surfaces of the second dummy stack unit 130D1 and the third dummy stack unit 130D2, and may extend to a portion of the third exposed surface 131a of the fifth electrode 131 of the third light-emitting unit 130L that does not include the charge blocking layer 150 thereon. The first conductive layer 160a may connect the electrode pad 14 to the fifth electrode 131 of the third light-emitting unit 130L. Therefore, the third light-emitting unit 130L may be electrically connected to the driving element 12 through the first conductive layer 160a. In addition, current supply may be blocked in a part covered by the charge blocking layer 150. The second conductive layer 160b may be on an upper surface of the sixth electrode 135 and may extend along the charge blocking layer 150 to be connected to the common electrode 16 described with reference to FIG. 2B.

FIG. 3B illustrates a simplified electrode connection structure of the micro light-emitting display apparatus 100B shown in FIG. 3A. Referring to FIG. 3B, the first exposed surface 111a of the first electrode 111 of the first light-emitting unit 110L may be connected to a corresponding electrode pad 14 by the first conductive layer 160a, the second exposed surface 121a of the third electrode 121 of the second light-emitting unit 120L may be connected to corresponding electrode pad 14 by the first conductive layer 160a, and the third exposed surface 131a of the fifth electrode 131 of the third light-emitting unit 130L may be connected to corresponding electrode pad 14 by the first conductive layer 160a. In addition, each of the second electrode 115 of the first light-emitting unit 110L, the fourth electrode 125 of the second light-emitting unit 120L, and the sixth electrode 135 of the third light-emitting unit 130L may be connected to the common electrode 16 by the second conductive layer 160b.

The micro light-emitting display apparatus 100B according to an embodiment may include a plurality of vertical stack structures, and light of different wavelengths may be emitted from a light-emitting unit in an upper layer in each of the vertical stack structures.

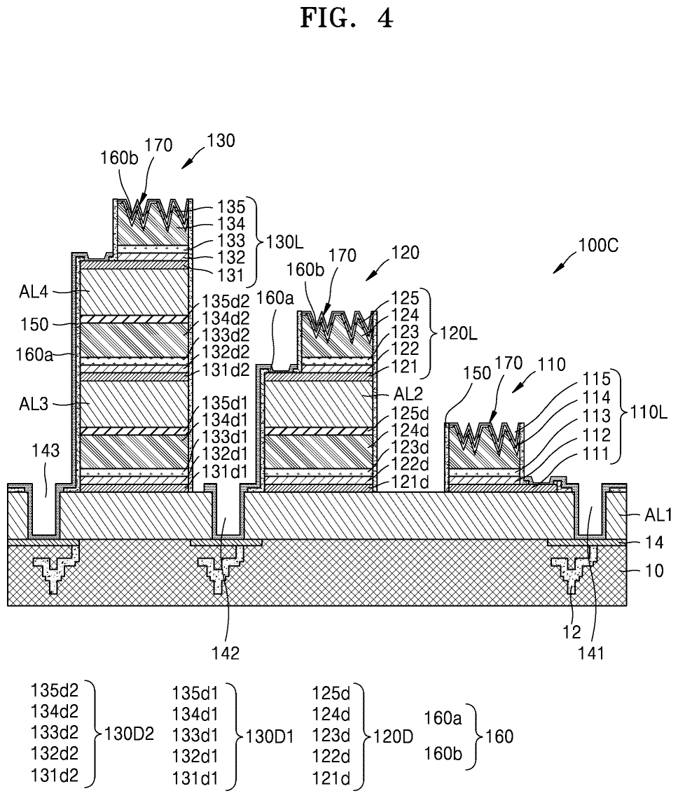

FIG. 4 illustrates an example in which the micro light-emitting display apparatus 100B shown in FIG. 3A further includes an uneven structure 170 in an upper portion of each of the first light-emitting unit 110L, the second light-emitting unit 120L, and the third light-emitting unit 130L.

A micro light-emitting display apparatus 100C may include the uneven structure 170 in the second semiconductor layer 114, the second electrode 115, and the second conductive layer 160b of the first light-emitting unit 110L. The uneven structure 170 may be in the fourth semiconductor layer 124, the fourth electrode 125, and the second conductive layer 160b of the second light-emitting unit 120L, and may be in the sixth semiconductor layer 134, the sixth electrode 135, and the second conductive layer 160b of the third light-emitting unit 130L. The uneven structure 170 may increase external quantum efficiency of light emitted from the first light-emitting unit 110L.

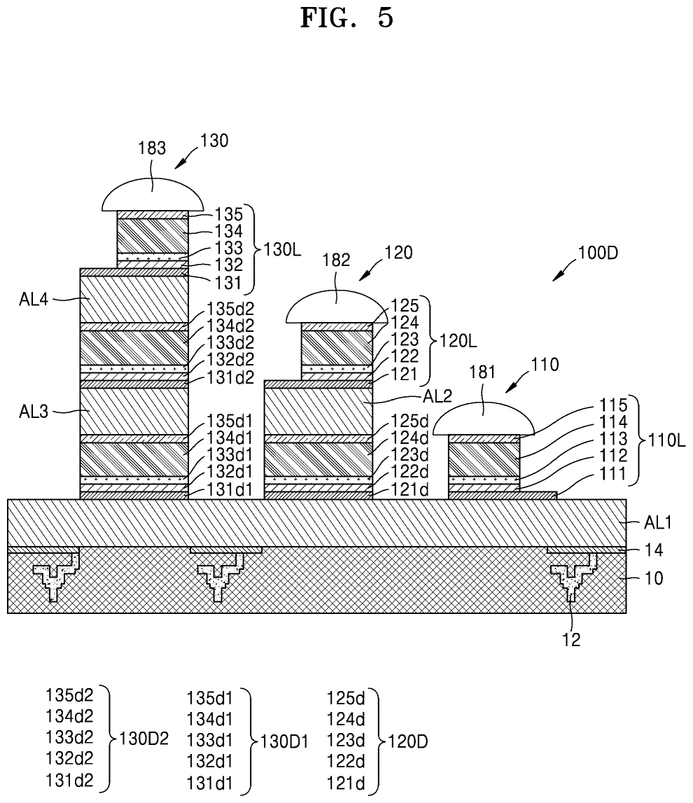

FIG. 5 illustrates an example in which the micro light-emitting display apparatus 100A shown in FIG. 2A further includes a first lens 181, a second lens 182, and a third lens 183.

A micro light-emitting display apparatus 100D may further include the first lens 181 at an upper portion of the first light-emitting unit 110L, the second lens 182 at an upper portion of the second light-emitting unit 120L, and the third lens 183 at an upper portion of the third light-emitting unit 130L.

The first lens 181 may be aligned with a central axis of the first active layer 113 of the first light-emitting unit 110L. When light emitted from the first active layer 113 travels upward, the light may be focused through the first lens 181. The second lens 182 may be aligned with a central axis of the second active layer 123 of the second light-emitting unit 120L. When light emitted from the second active layer 123 travels upward, the light may be focused through the second lens 182. The third lens 183 may be aligned with a central axis of the third active layer 133 of the third light-emitting unit 130L. When light emitted from the third active layer 133 travels upward, the light may be focused through the third lens 183.

In the micro light-emitting display apparatus 100D, light of different wavelengths may be emitted from the first light-emitting unit 110L, the second light-emitting unit 120L, and the third light-emitting unit 130L, respectively, which are located at upper portions of different light-emitting stack structures, and thus, the central axis alignment of the first lens 181, the second lens 182, and the third lens 183 respectively corresponding to the first light-emitting unit 110L, the second light-emitting unit 120L, and the third light-emitting unit 130L may be easily adjusted. The light may be focused through the first lens 181, the second lens 182, and the third lens 183, and thus, light focusing efficiency may be increased, and clarity of an image may be improved.

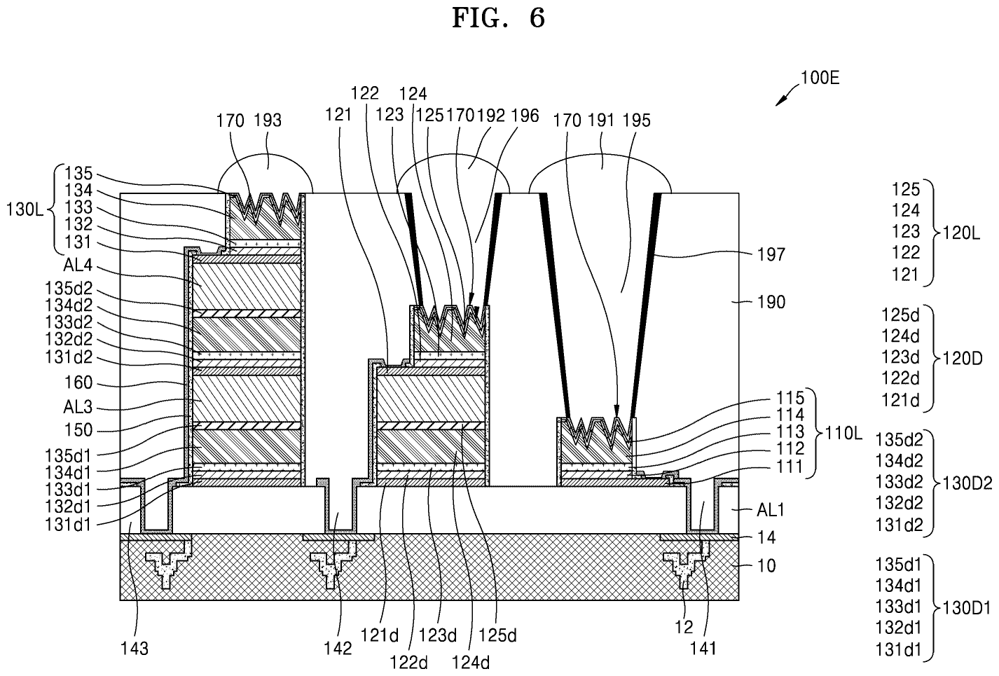

FIG. 6 illustrates an example in which the micro light-emitting display apparatus 100C shown in FIG. 4 further includes a first lens 191, a second lens 192, and a third lens 193.

A micro light-emitting display apparatus 100E according to an embodiment may include a planarization layer 190 to cover the first light-emitting stack structure 110, the second light-emitting stack structure 120, and the third light-emitting stack structure 130. The planarization layer 190 may planarize different heights of the first light-emitting stack structure 110, the second light-emitting stack structure 120, and the third light-emitting stack structure 130. The planarization layer 190 may include, for example, an acrylic polymer. However, the planarization layer 190 is not limited thereto. The planarization layer 190 may be provided up to the height of an upper surface of the third light-emitting stack structure 130. For example, an upper surface of the planarization layer 190 and the upper surface of the third light-emitting unit 130L may be at the same height. However, the height of the planarization layer 190 is not limited thereto.

A first hole 195 may be in the planarization layer 190 to expose an upper surface of the first light-emitting unit 110L, and a second hole 196 may be provided to expose an upper surface of the second light-emitting unit 120L. A separate hole may not be in an upper portion of the third light-emitting unit 130L. However, in another embodiment, a hole may also expose an upper surface of the third light-emitting unit 130L.

The first lens 191 may be in the first hole 195, and the second lens 192 may be in the second hole 196. The first lens 191 may fill the first hole 195, and have a convex shape at an upper surface thereof. That is, the first lens 191 may be formed as a single body from an upper portion of the first light-emitting unit 110L to a convex portion. Here, the first lens 191 is provided to fill the first hole 194, but may be in an upper portion of the first hole 194 while another layer is filled in the first hole 194. That is, a portion of the first lens 191 filling the first hole 195 and a convex portion may be formed as separate bodies. The first lens 191 may be arranged to have the same central axis as the central axis of the first active layer 113.

The second lens 192 may fill the second hole 196, and have a convex shape at an upper surface thereof. The third lens 193 may be in the upper portion of the third light-emitting unit 130L. That is, the second lens 192 may be formed as a single body from the upper portion of the second light-emitting unit 120L to the convex portion. Alternatively, as described with respect to the first lens 191, a portion of the second lens 192 filling the second hole 196 and a convex portion may be formed as separate bodies. The second lens 192 may be arranged to have the same central axis as the central axis of the second active layer 123.

The third lens 193 may be in the upper portion of the third light-emitting unit 130L and may have a convex shape. The third lens 193 may be directly in the upper portion of the third light-emitting unit 130L without a separate hole portion. However, the third lens 193 may be also in a hole portion.

A reflective layer 197 for reflecting light to sidewalls of the first hole 195 and the second hole 196 may be provided. Light emitted from the corresponding light-emitting unit may be reflected by the reflective layer 197 and emitted upward with high efficiency. The reflective layer 197 may include, for example, Al or Ag.

In the micro light-emitting display apparatus 100E, the convex portions of the first lens 191, the second lens 192, and the third lens 193 may be at the same height as each other. Thus, the light emitted from the first light-emitting unit 110L, the second light-emitting unit 120L, and the third light-emitting unit 130L, which are located at different heights, may be effectively focused.

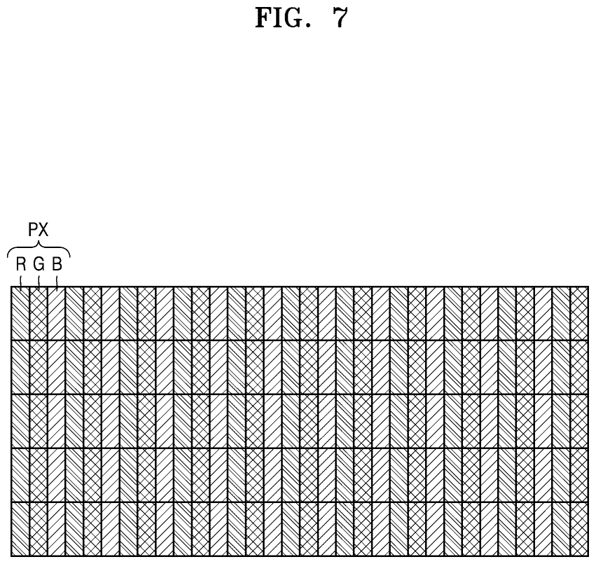

FIG. 7 illustrates an example of a pixel structure of a micro light-emitting display apparatus according to an embodiment.

The micro light-emitting display apparatus includes a plurality of pixels PX, and the pixel PX may be one unit displaying an image. Each of the pixels PX may include sub-pixels emitting different colors. An image may be displayed by controlling color and the amount of light from each sub-pixel. For example, the pixel PX may include a first sub-pixel (e.g., a red sub-pixel R) that emits red light, a second sub-pixel (e.g., a green sub-pixel G) that emits green light, and a third sub-pixel (e.g., a blue sub-pixel B) that emits blue light. The pixel structure may be applied to, for example, the micro light-emitting display apparatus 100A shown in FIG. 2A.

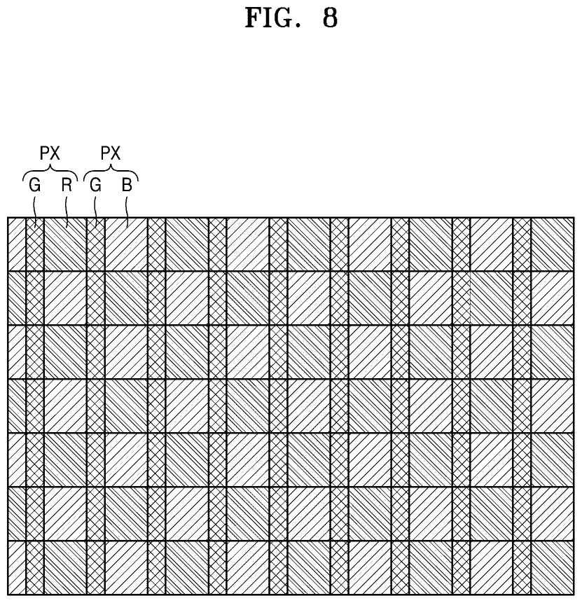

FIG. 8 illustrates another example of a pixel structure of a micro light-emitting display apparatus according to an embodiment.

The pixel structure shown in FIG. 8 may represent a pentile structure. The pixel PX may include a first sub-pixel (e.g., a green sub-pixel G) that emits green light and a second sub-pixel (e.g., a red sub-pixel R) that emits red light. Alternatively, the pixel PX may include a first sub-pixel (e.g., a green sub-pixel G) that emits green light and a second sub-pixel (e.g., a blue sub-pixel B) that emits blue light. A sub-pixel emitting red light and a sub-pixel emitting blue light may be shared with neighboring pixels to form a color. The pixel structure may be applied to, for example, the micro light-emitting display apparatus 100 shown in FIG. 1.

The micro light-emitting display apparatuses 100A, 100B, 100C, 100D, and 100E according to the embodiments may each have a plurality of vertical light-emitting stack structures having different heights, and emit light only from a light-emitting unit located at the uppermost portion in each of the plurality of vertical light-emitting stack structures. The plurality of vertical light-emitting stack structures may emit light of different wavelengths to form a color image. The micro light-emitting display apparatuses 100A, 100B, 100C, 100D, and 100E may form a color image without a color conversion member or a color filter that converts blue light into light of another wavelength.

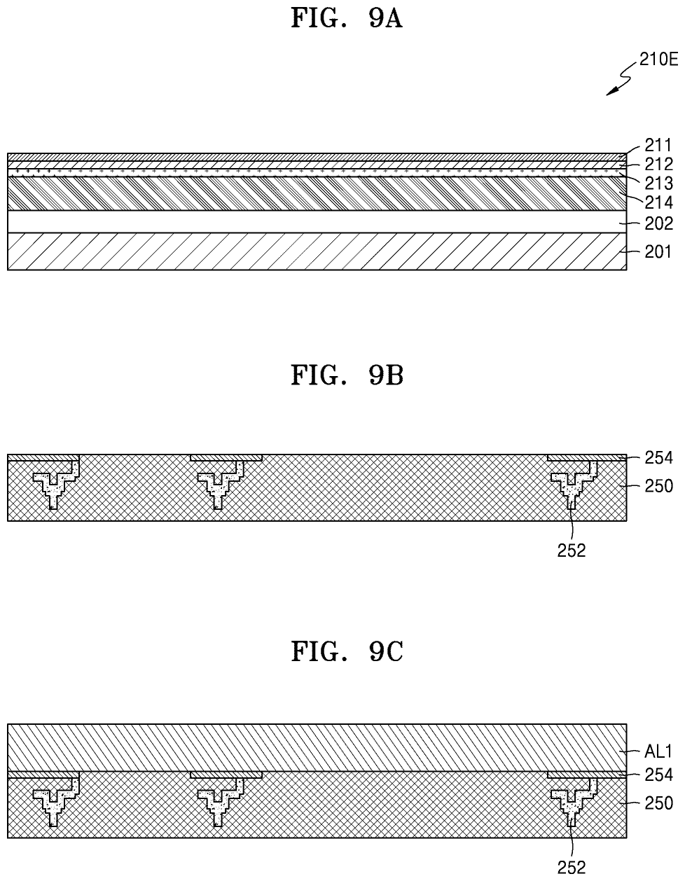

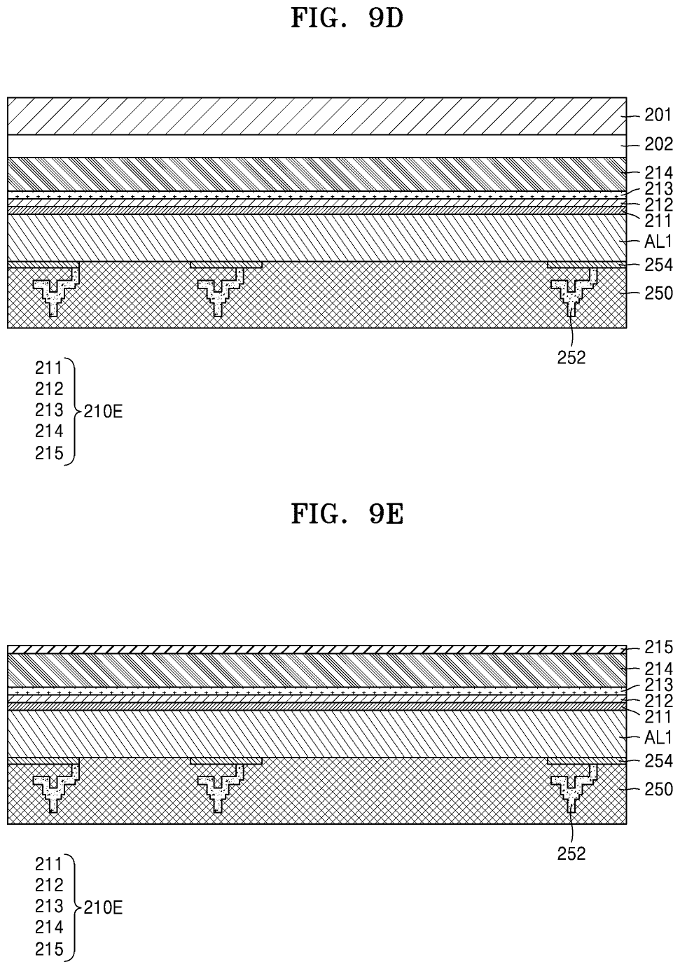

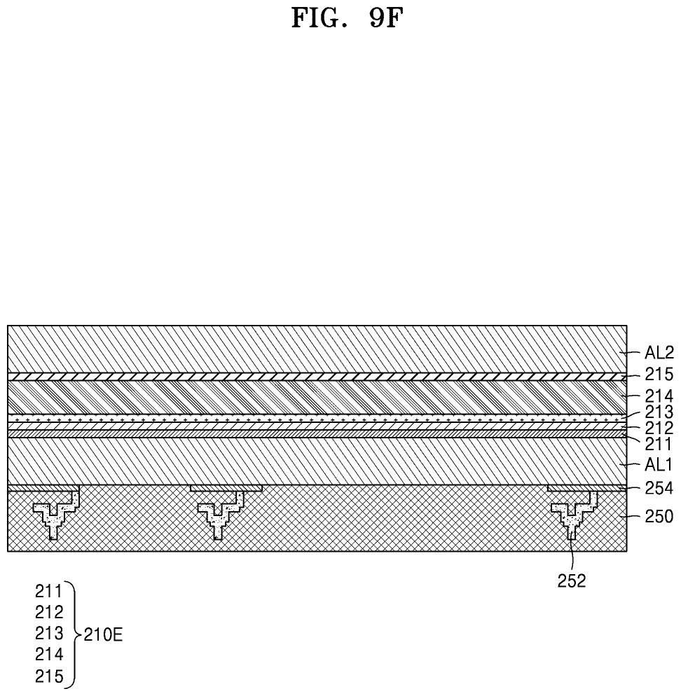

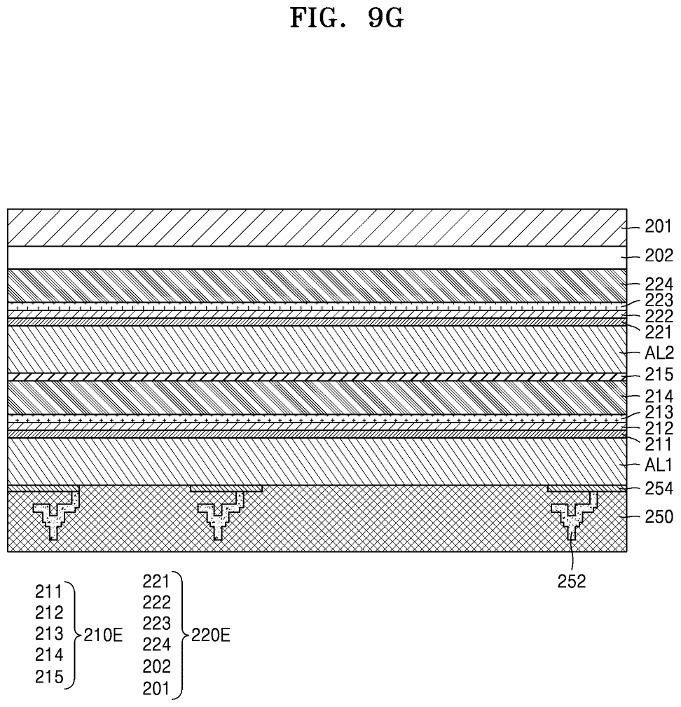

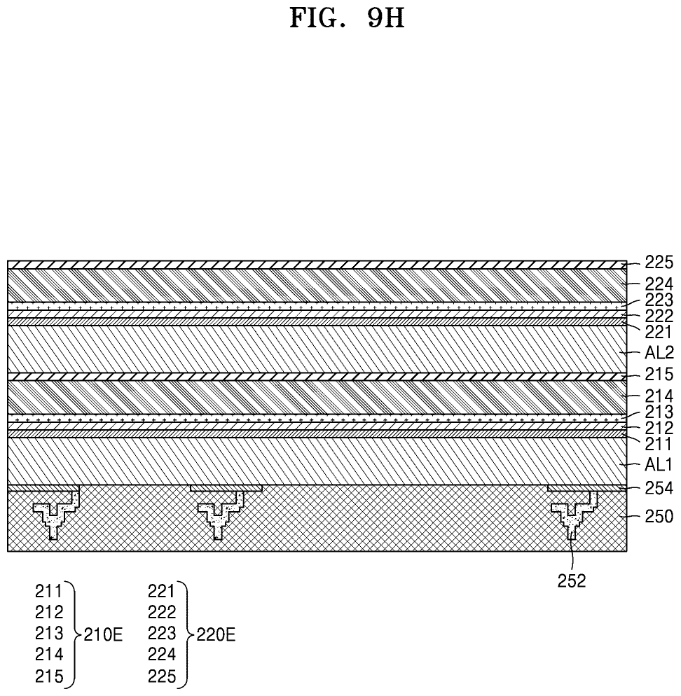

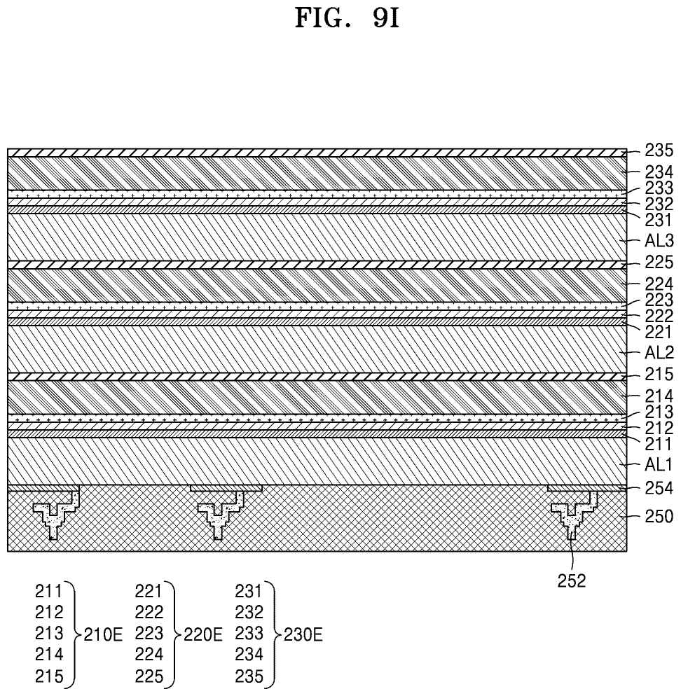

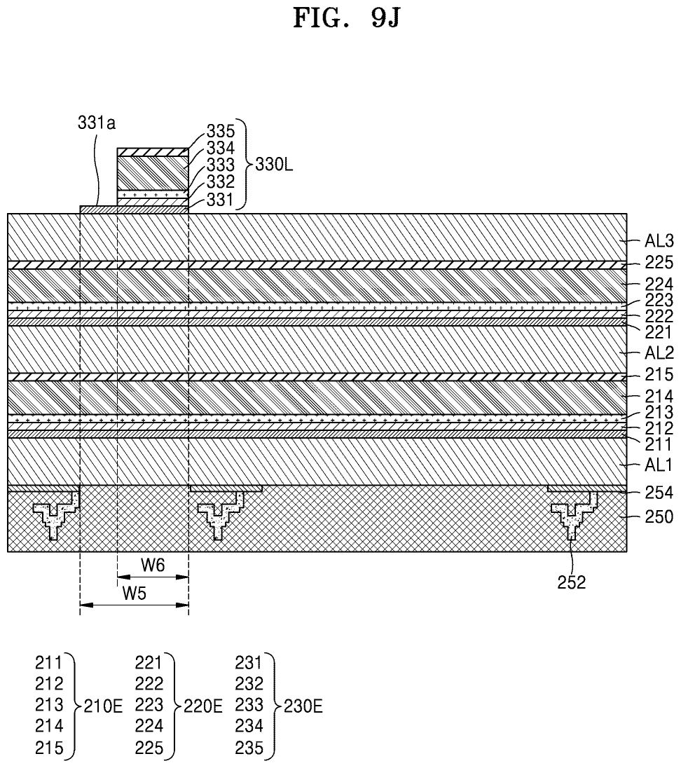

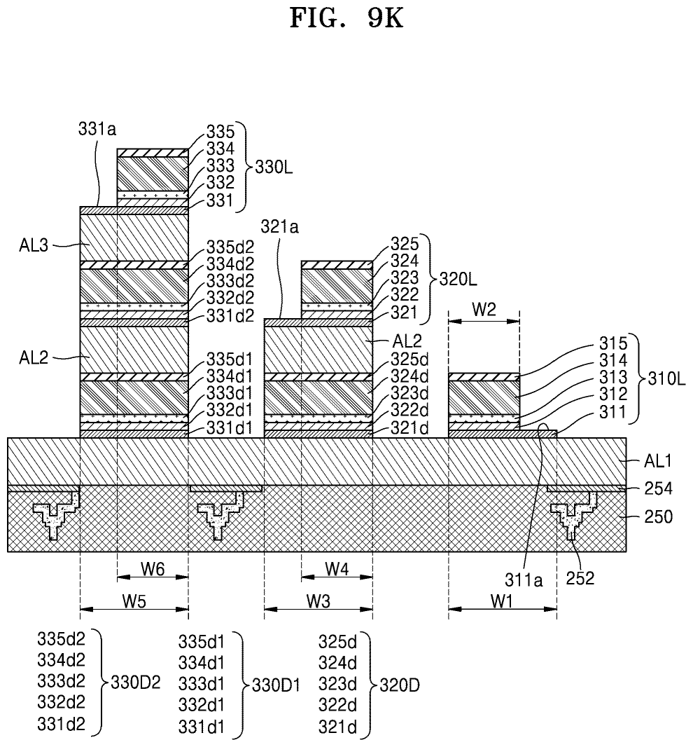

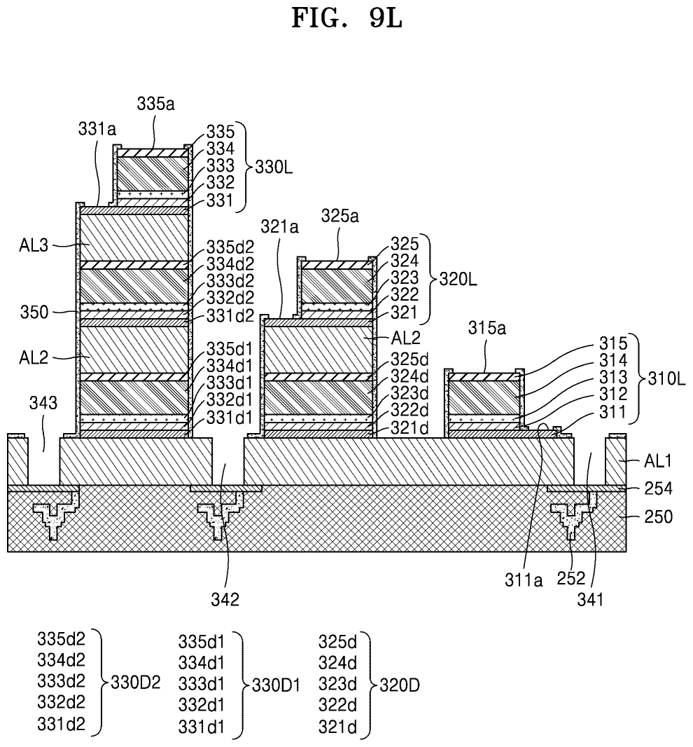

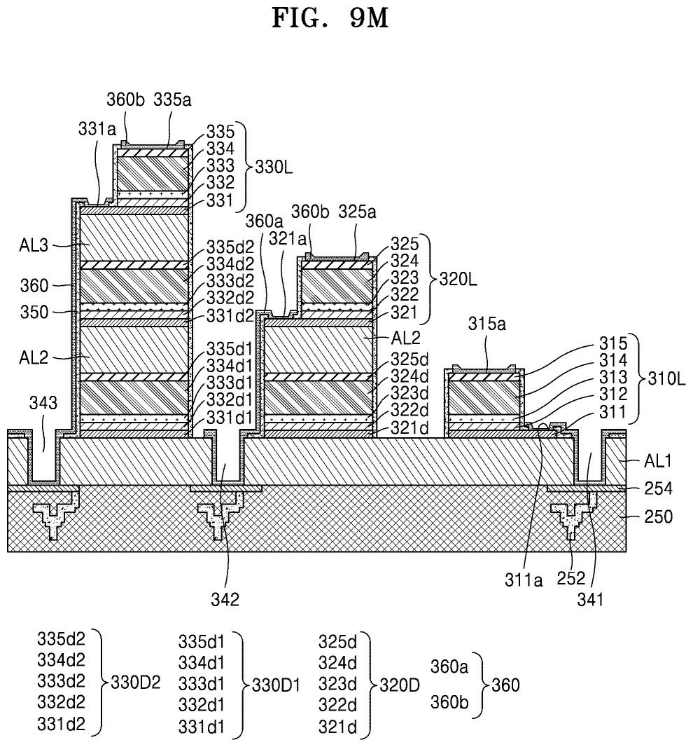

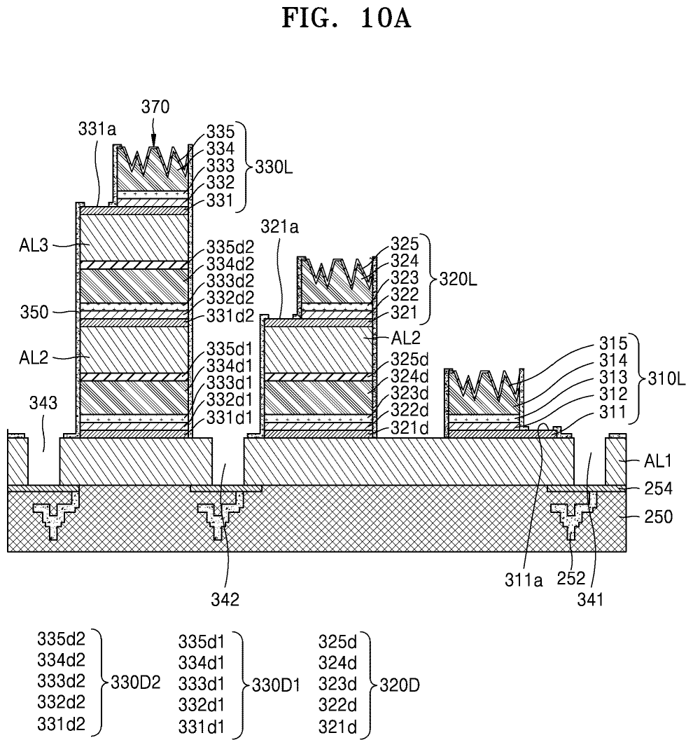

FIGS. 9A to 9M illustrate a method of manufacturing a micro light-emitting display apparatus according to an embodiment.

FIG. 9A illustrates a first epitaxial structure 210E. Referring to FIG. 9A, a second epitaxial semiconductor layer 214, a first epitaxial active layer 213, a first epitaxial semiconductor layer 212, and a first epitaxial electrode 211 may be in order deposited on an epitaxial substrate 201. Herein, expressions such as “first,” “second,” etc., may be used to distinguish components for convenience and are not limited to representing an order. In addition, “in order” and “sequentially” represent the order of layers, and do not exclude the intervention of other layers. The second epitaxial semiconductor layer 214, the first epitaxial active layer 213, the first epitaxial semiconductor layer 212, and the first epitaxial electrode 211 may be formed using, for example, a chemical vapor deposition (CVD) process, a physical vapor deposition (ALD) process, or an atomic layer deposition (ALD) process.

The epitaxial substrate 201 may include, for example, silicon, sapphire, GaAs or GaN. However, embodiments of the present disclosure are not limited thereto, and various epitaxial substrates 201 may be used. The second epitaxial semiconductor layer 214 may include an n-type semiconductor layer. However, in some cases, the second epitaxial semiconductor layer 214 may include a p-type semiconductor layer. For example, the second epitaxial semiconductor layer 214 may include a Group III-V compound semiconductor doped with an n-type. The first epitaxial active layer 213 may include a material that emits light of a first wavelength. For example, the first epitaxial active layer 213 may include a material that emits red light. However, embodiments of the present disclosure are not limited thereto. The first epitaxial semiconductor layer 212 may include a p-type semiconductor layer. However, in some cases, the first epitaxial semiconductor layer 212 may include an n-type semiconductor layer. For example, the first epitaxial semiconductor layer 212 may include a Group III-V compound semiconductor doped with a p-type.

A buffer layer 202 may be further formed between the epitaxial substrate 201 and the first epitaxial semiconductor layer 212. The buffer layer 202 may include a single-layer structure or a multi-layer structure, and may help the second epitaxial semiconductor layer 214 to grow well. The buffer layer 202 may relieve stress due to a grating constant difference between the epitaxial substrate 201 and the second epitaxial semiconductor layer 214. For example, the buffer layer 202 may be formed using the CVD process, the PVD process, or the ALD process. A lattice constant of the buffer layer 202 may have a value between a lattice constant of the epitaxial substrate 201 and a lattice constant of the second epitaxial semiconductor layer 214, or may have the same value as the lattice constant of the second epitaxial semiconductor layer 214. The buffer layer 202 may include, for example, a Group III-V compound semiconductor such as GaN, GaP, GaAs, etc. In addition, the buffer layer 202 may be doped with the same conductivity type as the second epitaxial semiconductor layer 214. For example, when the second epitaxial semiconductor layer 214 is doped with the n-type, the buffer layer 202 may include n-GaN, n-GaP, or n-GaAs, and when the second epitaxial semiconductor layer 214 is doped with the p-type, the buffer layer 202 may include p-GaN, p-GaP, or p-GaAs.

The first epitaxial electrode 211 may include, for example, Ag, Au, Al, Cr, or Ni, or an alloy thereof. However, the first epitaxial electrode 211 is not limited thereto. As described above, the first epitaxial structure 210E may be formed.

Referring to FIG. 9B, a driving element 252 may be formed in a backplane substrate 250. An electrode pad 254 connected to the driving element 252 may be formed. The driving element 252 may include at least one transistor and at least one capacitor.

Referring to FIG. 9C, the first bonding layer AL1 may be formed on the backplane substrate 250. The first bonding layer AL1 may include epoxy, polyimide (PI), benzocyclobutene (BCB), etc. The first bonding layer AL1 is formed on the backplane substrate 250 in FIG. 9C, but the first bonding layer AL1 may be formed on the first epitaxial electrode 211, or the first bonding layer AL1 may be formed on both the backplane substrate 250 and the first epitaxial electrode 211.

Referring to FIG. 9D, the first epitaxial structure 210E of FIG. 9A may be inverted and transferred to the backplane substrate 250. The backplane substrate 250 and the first epitaxial structure 210E may be coupled to each other by the first bonding layer AL1.

Referring to FIG. 9E, the epitaxial substrate 201 and the buffer layer 202 of the first epitaxial structure 210E may be removed. The first epitaxial substrate 210E and the buffer layer 202 may be removed by, for example, a laser lift off method, a polishing method, etc. The polishing method may be used together with a dry etching method. For example, when the first epitaxial substrate 210E is a sapphire substrate, the first epitaxial substrate 210E may be removed by the laser lift off method, and when the epitaxial substrate 201 is a silicon substrate, the epitaxial substrate 201 may be removed by the polishing method. The buffer layer 202 may be selectively removed. In addition, a second epitaxial electrode 215 may be formed on the second epitaxial semiconductor layer 214. The second epitaxial electrode 215 may include a transparent electrode material.

Referring to FIG. 9F, the second bonding layer AL2 may be formed on the second epitaxial electrode 215.

Referring to FIG. 9G, a second epitaxial structure 220E may be transferred to the second bonding layer AL2. The second epitaxial structure 220E may include an epitaxial substrate 201, a fourth epitaxial semiconductor layer 224, a second epitaxial active layer 223, a third epitaxial semiconductor layer 222, and a third epitaxial electrode 221, which are sequentially stacked. The buffer layer 202 may be further formed between the epitaxial substrate 201 and the fourth epitaxial semiconductor layer 224. The second epitaxial structure 220E may be manufactured by the same method as the method of manufacturing the first epitaxial structure 210E described above, and thus, a repeated description thereof may be omitted here. The second epitaxial active layer 223 of the second epitaxial structure 220E may include a material emitting light of a second wavelength. The second wavelength may be different from the first wavelength. The second wavelength may include, for example, a green wavelength. However, embodiments of the present disclosure are not limited thereto. The second epitaxial structure 220E may be inverted to allow the third epitaxial electrode 221 to face the second bonding layer AL2 and coupled to an upper portion of the first epitaxial structure 210E.

Referring to FIG. 9H, the epitaxial substrate 201 and the buffer layer 202 of FIG. 9G may be removed, and a fourth epitaxial electrode 225 may be formed on the fourth epitaxial semiconductor layer 224.

Referring to FIG. 9I, the third bonding layer AL3 may be formed on the fourth epitaxial electrode 225. In addition, the third epitaxial structure 230E may be transferred to the second epitaxial structure 220E. The third bonding layer AL3 may be formed on a third epitaxial structure 230E.

The third epitaxial structure 230E may include an epitaxial substrate, the sixth epitaxial semiconductor layer 234, the third epitaxial active layer 233, the fifth epitaxial semiconductor layer 232, and the fifth epitaxial electrode 231, which are sequentially stacked. The third epitaxial structure 230E may be manufactured by the same method as the method of manufacturing the first epitaxial structure 210E described above, and thus, a repeated description thereof may be omitted here. The third epitaxial active layer 233 of the third epitaxial structure 230E may include a material that emits light of a third wavelength. The third wavelength may be different from the first wavelength and the second wavelength. The third wavelength may include, for example, a blue wavelength. However, embodiments of the present disclosure are not limited thereto.

The first epitaxial active layer 213, the second epitaxial active layer 223, and the third epitaxial active layer 233 may generate light by recombining electrons and holes provided from the first to sixth epitaxial semiconductor layers 212, 214, 222, 224, 232, and 234, respectively. To this end, the first epitaxial active layer 213, the second epitaxial active layer 223, and the third epitaxial active layer 233 may each have a quantum well structure in which a quantum well is disposed between barriers. A wavelength of light generated by each of the first epitaxial active layer 213, the second epitaxial active layer 223, and the third epitaxial active layer 233 may be determined according to an energy band gap of a material constituting the quantum well of each of the first epitaxial active layer 213, the second epitaxial active layer 223, and the third epitaxial active layer 233. The first epitaxial active layer 213, the second epitaxial active layer 223, and the third epitaxial active layer 233 may each have only one quantum well, but may also have an MQW structure in which a plurality of quantum wells are disposed. The energy of the quantum well in a conduction band may be selected to be lower than the energy of the barrier. To this end, the barriers and the quantum wells of the first epitaxial active layer 213, the second epitaxial active layer 223, and the third epitaxial active layer 233 may include different compound semiconductors or compound semiconductors having different compositions.

According to an embodiment, the first to sixth epitaxial semiconductor layers 212, 214, 222, 224, 232, and 234, and the first to third epitaxial active layers 213, 223, and 233 may each include, for example, a Group III-V compound semiconductor based on GaN. For example, the first to sixth epitaxial semiconductor layers 212, 214, 222, 224, 232, and 234, and the first to third epitaxial active layers 213, 223, and 233 may each include a Group III-V compound semiconductor such as GaN, InGaN, AlInGaN, or AlGaInP.

The third epitaxial structure 230E may be inverted to allow the fifth epitaxial electrode 231 to face the third bonding layer AL3 and coupled to an upper portion of the second epitaxial structure 220E. Then, the epitaxial substrate 201 may be removed as described above. In addition, a sixth epitaxial electrode 235 may be formed on the sixth epitaxial semiconductor layer 234. Herein, the first epitaxial structure 210E, the second epitaxial structure 220E, and the third epitaxial structure 230E each basically refer to a structure in which layers corresponding to the epitaxial substrate 201 are stacked, but may also be used to refer to a stack structure in which the epitaxial substrate 201 is removed for convenience of description.

As described above, the method of manufacturing the micro light-emitting display apparatus according to an embodiment may include sequentially transferring the first epitaxial structure 210E, the second epitaxial structure 220E, and the third epitaxial structure 230E to the backplane substrate 250. Transfer may be easily performed at a wafer level without a complex and detailed alignment process. The first epitaxial structure 210E, the second epitaxial structure 220E, and the third epitaxial structure 230E have been described to be stacked with reference to FIG. 9I, but only the first epitaxial structure 210E and the second epitaxial structure 220E may be stacked to manufacture the micro light-emitting display apparatus 100 of FIG. 1. Meanwhile, an example in which the first epitaxial structure 210E, the second epitaxial structure 220E, and the third epitaxial structure 230E are separately formed and transferred has been described above, but the first epitaxial structure 210E, the second epitaxial structure 220E, and the third epitaxial structure 230E may be stacked in one (e.g., a same) process and processed in one (e.g., a same) transfer process.

Referring to FIG. 9J, the third light-emitting unit 330L may be formed by etching the third epitaxial structure 230E. The third light-emitting unit 330L may include a fifth electrode 331, a fifth semiconductor layer 332, a third active layer 333, a sixth semiconductor layer 334, and a sixth electrode 335. The third light-emitting unit 330L having a mesa structure may be formed by firstly etching the third epitaxial structure 230E to a depth of the fifth epitaxial electrode 231 by using a first mask, and secondly etching the third epitaxial structure 230E to a depth of the fifth epitaxial semiconductor layer 232 by using a second mask. A stack structure having the fifth width W5 may be formed during first etching, and the third light-emitting unit 330L including the third active layer 333 having the sixth width W6 may be formed during second etching. The fifth width W5 may be greater than the sixth width W6. Therefore, an exposed surface 331a may be formed in the fifth electrode 331.

The first and second mask may be formed as, for example, a SiO₂ hard mask. The third light-emitting unit 330L may be formed by etching regions not covered with a mask to a certain depth through, for example, a dry etching process. In this regard, a structure formed by the dry etching process may have an inclined sidewall. In order to make a width of the third light-emitting unit 330L relatively constant, a wet etching process may be additionally performed. The dry etching process may use, for example, inductively coupled plasma (ICP). The wet etching process may be performed using, for example, a potassium hydroxide (KOH) solution or a tetramethylammonium hydroxide (TMAH) solution as an etchant.

Referring to FIG. 9K, the second light-emitting unit 320L and the first light-emitting unit 310L may be formed in the same manner as described with reference to FIG. 9J. To avoid redundant descriptions, a repeated description of a process of manufacturing each of the second light-emitting unit 320L and the first light-emitting unit 310L may be omitted herein.

The second light-emitting unit 320L may include a third electrode 321, a third semiconductor layer 322, a second active layer 323, a fourth semiconductor layer 324, and a fourth electrode 325. The second light-emitting unit 320L having a mesa structure may be formed by firstly etching the second epitaxial structure 220E to a depth of the third epitaxial electrode 221 by using a mask, and secondly etching the second epitaxial structure 220E to a depth of the third epitaxial semiconductor layer 222 by using another mask. A stack structure having the third width W3 may be formed during first etching, and the second light-emitting unit 320L including the second active layer 323 having the fourth width W4 may be formed during second etching. The third width W3 may be greater than the fourth width W4. Therefore, an exposed surface 321a may be formed in the third electrode 321.

The first light-emitting unit 310L may include a first electrode 311, a first semiconductor layer 312, a first active layer 313, a second semiconductor layer 314, and a second electrode 315. The first light-emitting unit 310L having a mesa structure may be formed by firstly etching the first epitaxial structure 210E to a depth of the first epitaxial electrode 211 by using a mask, and secondly etching the first epitaxial structure 210E to a depth of the first epitaxial semiconductor layer 212 by using another mask. A stack structure having the first width W1 may be formed during first etching, and the first light-emitting unit 310L including the first active layer 313 having the second width W2 may be formed during second etching. The first width W1 may be greater than the second width W2. Therefore, an exposed surface 311a may be formed in the first electrode 311.

As described above, the first light-emitting stack structure 310, the second light-emitting stack structure 320, and the third light-emitting stack structure 330 having different heights may be formed on the backplane substrate 250.

Referring to FIG. 9L, a charge blocking layer 350 may be deposited over the entire structure shown in FIG. 9K. The charge blocking layer 350 may include AlN, AlOx, SiO₂, or a combination thereof. In addition, the charge blocking layer 350 may be patterned to expose a partial upper region of the first bonding layer AL1, the exposed surface 311a of the first electrode 311, the exposed surface 321a of the third electrode 321, the exposed surface 331a of the fifth electrode 331, and upper surfaces 315a, 325a, and 335a of the second electrode 315, the fourth electrode 325, and the sixth electrode 335. In addition, a first groove 341, a second groove 342, and a third groove 343 may be formed by etching the first bonding layer AL1. The first groove 341, the second groove 342, and the third groove 343 may be formed through the first bonding layer AL1 such that the electrode pads 254 are exposed.

Referring to FIG. 9M, a conductive layer 360 may be deposited on the charge blocking layer 350. The conductive layer 360 may be deposited to cover the entire structure and patterned to form a wiring structure. The conductive layer 360 may include a first conductive layer 360a and a second conductive layer 360b. The first conductive layer 360a may be deposited on the first groove 341, the second groove 342, and the third groove 343 and connected to the electrode pads 254. In addition, the first conductive layer 360a may extend to the exposed surface 331a of the fifth electrode 331 along one sidewall of the third light-emitting stack structure 330. The first conductive layer 360a may extend to the exposed surface 321a of the third electrode 321 along one sidewall of the second light-emitting stack structure 320. The first conductive layer 360a may extend to the exposed surface 311a of the first electrode 311 along one sidewall of the first light-emitting stack structure 310. The second conductive layer 360b may be formed on the second electrode 315 of the first light-emitting unit 310L, the fourth electrode 325 of the second light-emitting unit 320L, and the sixth electrode 335 of the third light-emitting unit 330L.

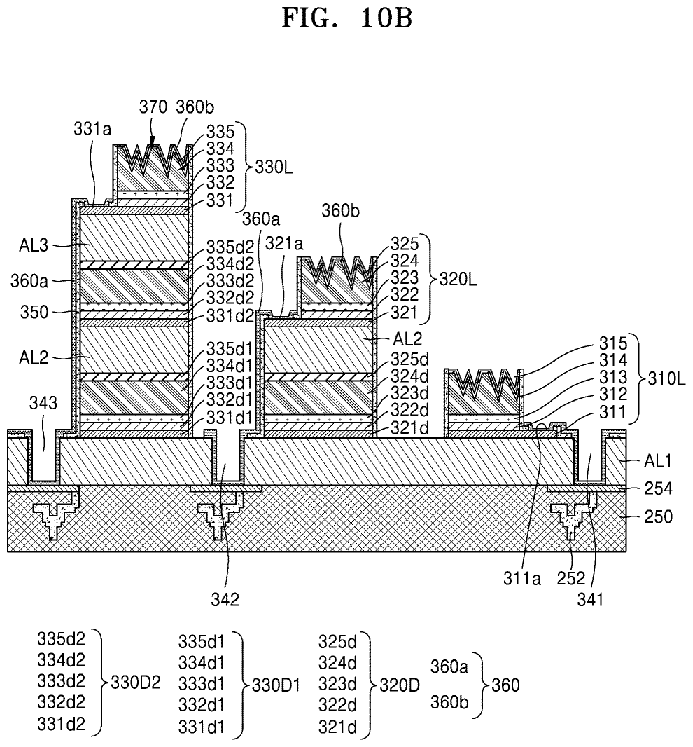

Referring to FIG. 10A, an uneven structure 370 may be formed in the structure shown in FIG. 9L. The uneven structure 370 may be formed in upper portions of the first light-emitting unit 310L, the second light-emitting unit 320L, and the third light-emitting unit 330L. The uneven structure 370 may be patterned by using KOH or TMAH. The uneven structure 370 may be formed in the upper portions of the first light-emitting unit 310L, the second light-emitting unit 320L, and the third light-emitting unit 330L, thereby increasing light emission efficiency and external quantum efficiency.

Referring to FIG. 10B, the conductive layer 360 may be formed on the structure shown in FIG. 10A. The conductive layer 360 is substantially the same as that described with reference to FIG. 9M, and thus, a repeated description thereof may be omitted here.

As described above, the method of manufacturing the micro light-emitting display apparatus according to an embodiment may easily transfer a plurality of epitaxial structures to a backplane substrate at a wafer level, and form a plurality of light-emitting stack structures with different heights and different emission wavelengths through an etching process.

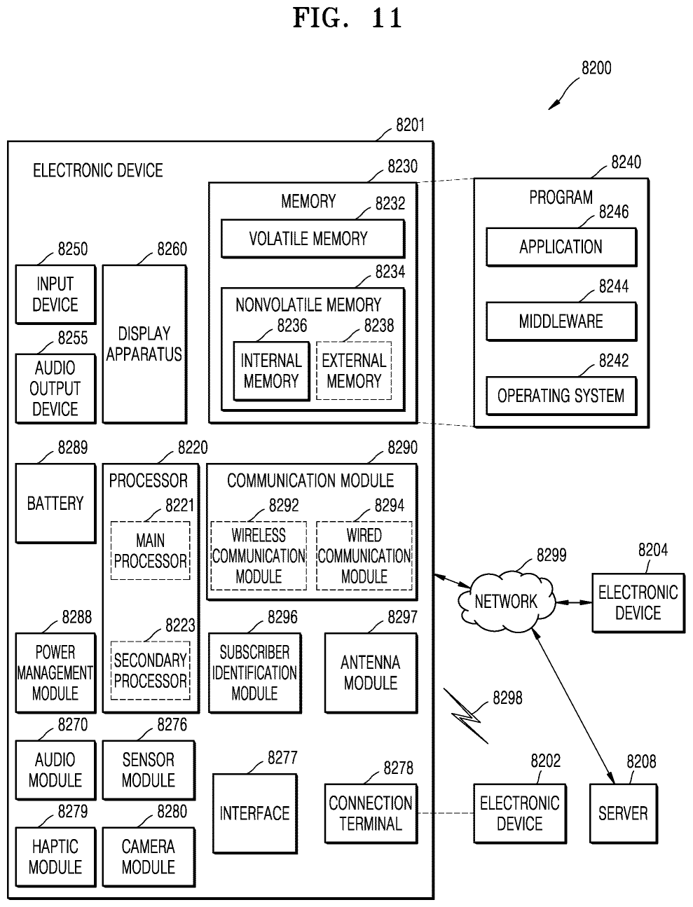

FIG. 11 is a schematic block diagram of an electronic device 8201 including a display apparatus 8260 according to an embodiment. Referring to FIG. 11, the electronic device 8201 may be provided in a network environment 8200. In the network environment 8200, the electronic device 8201 may communicate with another electronic device 8202 through a first network 8298 (e.g., a short-range wireless communication network, etc.), or communicate with another electronic device 8204 and/or a server 8208 through a second network 8299 (e.g., a remote wireless communication network). The electronic device 8201 may communicate with the electronic device 8204 through the server 8208. The electronic device 8201 may include a processor 8220, a memory 8230, an input device 8250, an audio output device 8255, the display apparatus 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. In the electronic device 8201, some of these components may be omitted and/or other components may be added. Some of these components may be implemented as one integrated circuit. For example, the sensor module 8276 (e.g., fingerprint sensor, iris sensor, illuminance sensor, etc.) may be implemented by being embedded in the display apparatus 8260 (e.g., display, etc.).

The processor 8220 may execute software (e.g., the program 8240, etc.) to control one or a plurality of other components (e.g., hardware, software components, etc.) of the electronic device 8201 connected to the processor 8220, and perform various data processing or operations. As part of data processing or operation, the processor 8220 may load commands and/or data received from other components (e.g., the sensor module 8276, the communication module 8290, etc.) into a volatile memory 8232, process commands and/or data stored in the volatile memory 8232, and store result data in a nonvolatile memory 8234. The nonvolatile memory 8234 may include an internal memory 8236 and an external memory 8238. The processor 8220 may include a main processor 8221 (e.g., a central processing unit, an application processor, etc.) and a secondary processor 8223 (e.g., a graphics processing unit, an image signal processor, a sensor hub processor, a communication processor, etc.) that may be operated independently or together. The secondary processor 8223 may use less power than the main processor 8221 and may perform specialized functions.

The secondary processor 8223 may control functions and/or states related to some of the components of the electronic device 8202 (e.g., the display apparatus 8260, the sensor module 8276, the communication module 8290, etc.) instead of the main processor 8221 while the main processor 8221 is in an inactive state (sleep state), or with the main processor 8221 while the main processor 8221 is in an active state (application execution state). The secondary processor 8223 (e.g., an image signal processor, a communication processor, etc.) may be implemented as part of other functionally related components (e.g., the camera module 8280, the communication module 8290, etc.)

The memory 8230 may store various data required by components of the electronic device 8201 (e.g., the processor 8220, the sensor module 8276, etc.). The data may include, for example, software (e.g., the program 8240, etc.) and input data and/or output data for commands related thereto. The memory 8230 may include the volatile memory 8232 and/or the nonvolatile memory 8234.

The program 8240 may be stored as software in the memory 8230 and may include an operating system 8242, a middleware 8244, and/or an application 8246.

The input device 8250 may receive commands and/or data to be used for components (e.g., the processor 8220, etc.) of the electronic device 8201 from outside (e.g., a user) of the electronic device 8201. The input device 8250 may include a remote controller, a microphone, a mouse, a keyboard, and/or a digital pen (e.g., a stylus pen).

The audio output device 8255 may output an audio signal to the outside of the electronic device 8201. The audio output device 8255 may include a speaker and/or a receiver. The speaker may be used for general purposes such as multimedia playback or recording playback, and the receiver may be used to receive incoming calls. The receiver may be combined as a part of the speaker or may be implemented as an independent separate device.

The display apparatus 8260 may visually provide information to the outside of the electronic device 8201. The display apparatus 8260 may include the display, a hologram device, or a projector and a control circuit for controlling the device. The display apparatus 8260 may include the display apparatus according to an embodiment. The display apparatus 8260 may include a touch circuit set to sense a touch, and/or a sensor circuit (e.g., a pressure sensor) set to measure the strength of a force generated by the touch.

The audio module 8270 may convert sound into an electrical signal, or conversely, may convert an electrical signal into sound. The audio module 8270 may acquire sound through the input device 8250 or output sound through speakers and/or headphones of the audio output device 8255, and/or another electronic device (e.g., the electronic device 8102) directly or wirelessly connected to electronic device 8201.

The sensor module 8276 may detect an operating state (e.g., power, temperature, etc.) of the electronic device 8201 or an external environmental state (e.g., a user state, etc.), and generate an electrical signal and/or data value corresponding to the detected state. The sensor module 8276 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more specified protocols that may be used for the electronic device 8201 to connect directly or wirelessly with another electronic device (e.g., the electronic device 8102). The interface 8277 may include a High Definition Multimedia Interface (HDMI), a Universal Serial Bus (USB) interface, an SD card interface, and/or an audio interface.

The connection terminal 8278 may include a connector through which the electronic device 8201 may be physically connected to another electronic device (e.g., the electronic device 8102). The connection terminal 8278 may include an HDMI connector, a USB connector, an SD card connector, and/or an audio connector (e.g., a headphone connector).

The haptic module 8279 may convert an electrical signal into a mechanical stimulus (e.g., vibration, movement, etc.) or an electrical stimulus that a user may perceive through a tactile or motor sense. The haptic module 8279 may include a motor, a piezoelectric element, and/or an electrical stimulation device.

The camera module 8280 may capture a still image and a video. The camera module 8280 may include a lens assembly including one or more lenses, image sensors, image signal processors, and/or flashes. The lens assembly included in the camera module 8280 may collect light emitted from a subject that is a target of image capturing.

The power management module 8288 may manage power supplied to the electronic device 8201. The power management module 8288 may be implemented as a part of a Power Management Integrated Circuit (PMIC).

The battery 8289 may supply power to components of the electronic device 8201. The battery 8289 may include a non-rechargeable primary cell, a rechargeable secondary cell, and/or a fuel cell.

The communication module 8290 may support establishing a direct (wired) communication channel and/or a wireless communication channel, and performing communication through the established communication channel between the electronic device 8201 and other electronic devices (e.g., the electronic device 8102, the electronic device 8104, the server 8108, etc.) The communication module 8290 may include one or more communication processors that operate independently of the processor 8220 (e.g., an application processor) and support direct communication and/or wireless communication. The communication module 8290 may include a wireless communication module 8292 (e.g., a cellular communication module, a short-range wireless communication module, a Global Navigation Satellite System (GNSS) communication module, and the like) and/or a wired communication module 8294 (e.g., a local area network (LAN) communication module, a power line communication module, etc.) Among these communication modules, a corresponding communication module may communicate with other electronic devices through a first network 8298 (e.g., a short-range communication network such as Bluetooth, WiFi Direct, or Infrared Data Association (IrDA)) or a second network 8299 (e.g., a cellular network, the Internet, or a telecommunication network such as a computer network (e.g., LAN, WAN, etc.)) These various types of communication modules may be integrated into one component (e.g., a single chip, and the like), or may be implemented as a plurality of separate components (e.g., a plurality of chips). The wireless communication module 8292 may check and authenticate the electronic device 8201 in a communication network such as the first network 8298 and/or the second network 8299 using the subscriber information (e.g., international mobile subscriber identifier (IMSI), etc.) stored in the subscriber identification module 8296.

The antenna module 8297 may transmit signals and/or power to the outside (e.g., other electronic devices) or receive signals and/or power from the outside. The antenna may include a radiator made of a conductive pattern formed on a substrate (e.g., PCB, etc.) The antenna module 8297 may include one or a plurality of antennas. When multiple antennas are included, an antenna suitable for a communication method used in a communication network such as the first network 8298 and/or the second network 8299 may be selected from the plurality of antennas by the communication module 8290. Signals and/or power may be transmitted or received between the communication module 8290 and another electronic device through the selected antenna. In addition to the antenna, other components (e.g., RFIC) may be included as part of the antenna module 8297.

Some of the components are connected to each other and may exchange signals (e.g., commands, data, etc.) through communication method between peripheral devices (e.g., bus, General Purpose Input and Output (GPIO), Serial Peripheral Interface (SPI), Mobile Industry Processor Interface (MIPI), etc.)

The command or data may be transmitted or received between the electronic device 8201 and the electronic device 8204 (e.g., an external electronic device) through the server 8108 connected to the second network 8299. The other electronic devices 8202 and 8204 may be the same or different types of devices as or from the electronic device 8201. All or some of the operations executed by the electronic device 8201 may be executed by one or more of the other electronic devices 8202, 8204, and 8208. For example, when the electronic device 8201 needs to perform a certain function or service, instead of executing the function or service itself, the electronic device 8201 may request one or more other electronic devices to perform the function or part or all of the service. One or more other electronic devices that receive the request may execute an additional function or service related to the request, and transmit a result of the execution to the electronic device 8201. To this end, cloud computing, distributed computing, and/or client-server computing technology may be used.

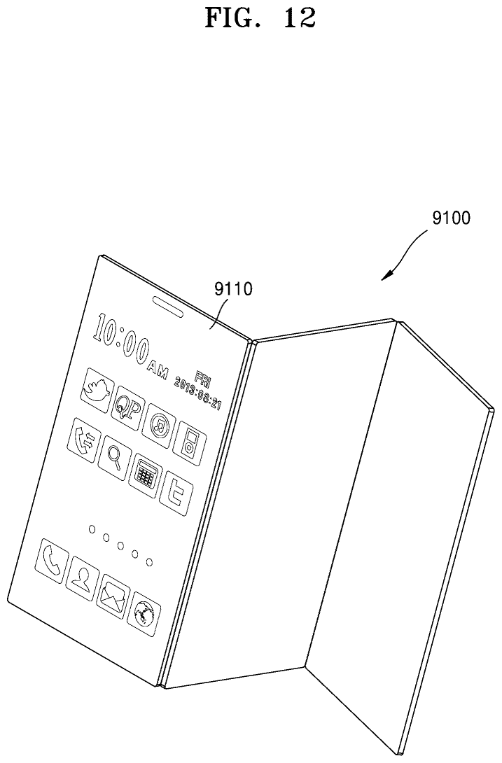

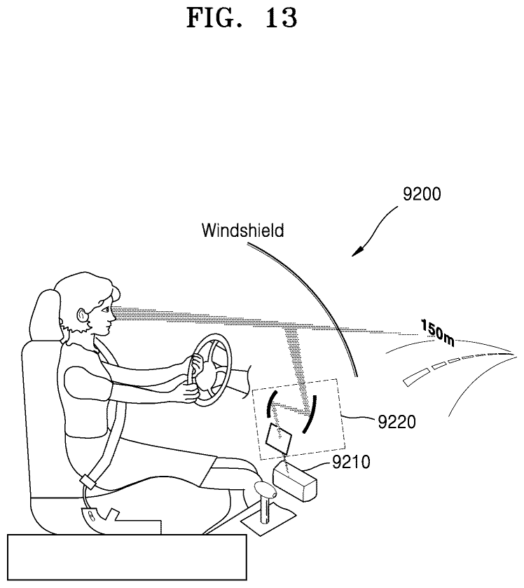

FIG. 12 illustrates an example in which a micro light-emitting display apparatus is applied to a mobile device 9100 according to an embodiment. The mobile device 9100 may include a display apparatus 9110. The display apparatus 9110 may include the micro light-emitting display apparatus according to an embodiment. The display apparatus 9110 may have a foldable structure such as, for example, a multi-foldable structure.

FIG. 13 illustrates an example in which a micro light-emitting display apparatus is applied to a vehicle. The micro light-emitting display apparatus may be the vehicle head-up display apparatus 9200, and may include a display 9210 provided in an area of a vehicle, and a light path changing member 9220 that converts an optical path so that a driver may see the image generated on the display 9210.

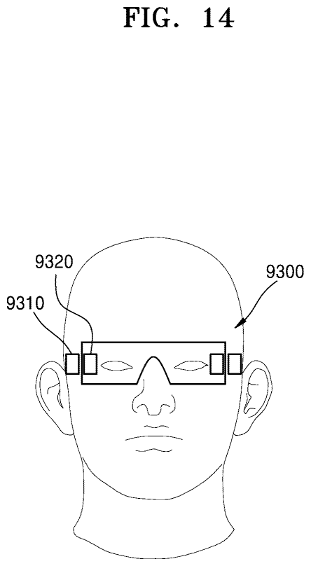

FIG. 14 illustrates an example in which a micro light-emitting display apparatus is applied to augmented reality (AR) or virtual reality (VR) glasses 9300 according to an embodiment. The AR or VR glasses 9300 may include a projection system 9310 that forms an image, and an element 9320 that guides the image from the projection system 9310 into the user's eye. The projection system 9310 may include the display apparatus according to an embodiment.

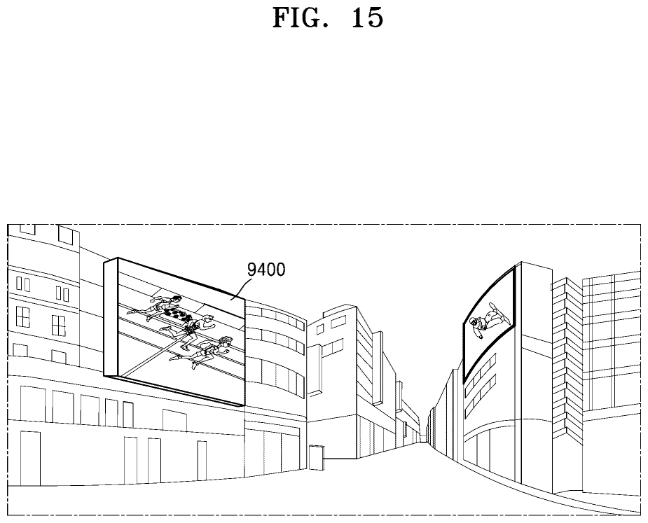

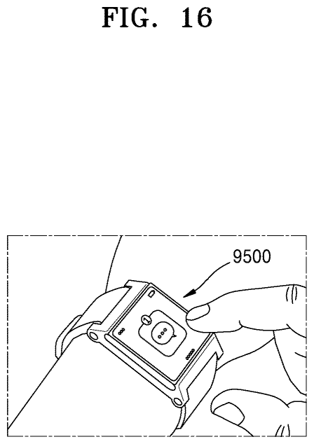

FIG. 15 illustrates an example in which a micro light-emitting display apparatus is applied to a signage 9400 according to an embodiment. The signage 9400 may be used for outdoor advertisement using a digital information display, and may control advertisement contents and the like through a communication network. The signage 9400 may be implemented through, for example, the electronic device described with reference to FIG. 11.

FIG. 16 illustrates an example in which a micro light-emitting display apparatus is applied to a wearable display 9500 according to an embodiment. The wearable display 9500 may include the display apparatus according to an embodiment, and may be implemented through the electronic device described with reference to FIG. 11.

The light-emitting device according to embodiments or the display apparatus including the light-emitting device may also be applied to various products such as a rollable TV and a stretchable display.

An embodiment may implement the micro light-emitting display apparatus that displays a high-resolution color image by using a micro light-emitting device. The micro light-emitting display apparatus according to an embodiment may be simplified by using a micro light-emitting structure that directly displays a green color or a red color without a process of converting blue light into green light or red light.

A method of manufacturing the micro light-emitting display apparatus according to an embodiment may manufacture the micro light-emitting display apparatus that displays a color image by transferring an epitaxial structure.

Example embodiments described herein should be considered in a descriptive sense only and not for purposes of limitation. Descriptions of features or aspects within each embodiment should typically be considered as available for other similar features or aspects in other embodiments. While one or more non-limiting example embodiments have been described with reference to the figures, it will be understood by those of ordinary skill in the art that various changes in form and details may be made therein without departing from the spirit and scope of the present disclosure.

What is claimed is:

1. A micro light-emitting display apparatus comprising:
a backplane substrate comprising at least one driving element;
a first light-emitting stack structure on the backplane substrate; and
a second light-emitting stack structure on the backplane substrate and spaced apart from the first light-emitting stack structure,
wherein the first light-emitting stack structure comprises a first light-emitting unit comprising a first electrode, a first semiconductor layer, a first active layer configured to emit light of a first wavelength, a second semiconductor layer, and a second electrode, which are stacked in order,
wherein the second light-emitting stack structure comprises a first dummy stack unit and a second light-emitting unit, and a height of the first dummy stack unit and a height of the first light-emitting unit are at a same level,
wherein the second light-emitting unit comprises a third electrode, a third semiconductor layer, a second active layer configured to emit light of a second wavelength different from the first wavelength, a fourth semiconductor layer, and a fourth electrode, which are stacked in order on an upper portion of the first dummy stack unit in a direction perpendicular to the backplane substrate,
wherein the first electrode has a width greater than a width of the first semiconductor layer, comprises a first exposed surface exposed from the first semiconductor layer, and is connected to the at least one driving element, and
wherein the third electrode has a width that is greater than a width of the third semiconductor layer, comprises a second exposed surface exposed from the third semiconductor layer, and is connected to the at least one driving element.

2. The micro light-emitting display apparatus of claim 1, wherein the first dummy stack unit has a width that is greater than a width of the second active layer of the second light-emitting unit.

3. The micro light-emitting display apparatus of claim 1, wherein a the first dummy stack unit has a width that is the same as a width of a third electrode layer.

4. The micro light-emitting display apparatus of claim 1, wherein, at a same height, the first dummy stack unit comprises a material layer that is the same as a material layer of the first light-emitting unit.

5. The micro light-emitting display apparatus of claim 1, wherein the first dummy stack unit is configured to receive no voltage.

6. The micro light-emitting display apparatus of claim 1, further comprising:
a third light-emitting stack structure spaced apart from the second light-emitting stack structure,
wherein the third light-emitting stack structure comprises:
a second dummy stack unit having a height that is at the same level as the height of the first light-emitting unit;
a third dummy stack unit on an upper portion of the second dummy stack unit having a height that is at a same level as a height of the second light-emitting unit; and
a third light-emitting unit,
wherein the third light-emitting unit comprises a fifth electrode, a fifth semiconductor layer, a third active layer configured to emit light of a third wavelength different from the first wavelength and the second wavelength, a sixth semiconductor layer, and a sixth electrode, which are stacked in order on an upper portion of the third dummy stack unit in the direction perpendicular to the backplane substrate, and
wherein the fifth electrode has a width that is greater than a width of the fifth semiconductor layer, comprises a third exposed surface exposed from the fifth semiconductor layer, and is connected to the at least one driving element.

7. The micro light-emitting display apparatus of claim 6, wherein the second dummy stack unit and the third dummy stack unit are configured to receive no voltage.

8. The micro light-emitting display apparatus of claim 1, further comprising:
a first conductive layer configured to electrically connect the at least one driving element to the first exposed surface and the second exposed surface.

9. The micro light-emitting display apparatus of claim 1, wherein each of the first light-emitting unit and the second light-emitting unit has an uneven structure.

10. The micro light-emitting display apparatus of claim 1, further comprising:
a first lens on an upper portion of the first light-emitting unit; and
a second lens on an upper portion of the second light-emitting unit.

11. The micro light-emitting display apparatus of claim 1, further comprising:
a planarization layer on the first light-emitting stack structure and the second light-emitting stack structure, wherein the planarization layer includes a first hole that exposes the first light-emitting unit;
a first lens within the first hole, wherein an upper portion of the first lens comprises a convex shape; and
a second lens on an upper portion of the second light-emitting unit.

12. The micro light-emitting display apparatus of claim 1, further comprising:
a bonding layer between the backplane substrate and the first light-emitting stack structure and between the backplane substrate and the second light-emitting stack structure.

13. The micro light-emitting display apparatus of claim 12, wherein the bonding layer has a thickness in a range of 0.3 μm to 5 μm.

14. The micro light-emitting display apparatus of claim 1, further comprising: a bonding layer between the first dummy stack unit and the second light-emitting unit.

15. A method of manufacturing a micro light-emitting display apparatus, the method comprising:
forming a first epitaxial structure by stacking in order a second semiconductor layer, a first active layer, a first semiconductor layer, and a first electrode on a first epitaxial substrate;
forming a backplane substrate comprising at least one driving element;
coupling the first epitaxial structure to the backplane substrate;
removing the first epitaxial substrate from the first epitaxial structure;
forming a second electrode in the first epitaxial structure;
forming a second epitaxial structure by stacking in order a fourth semiconductor layer, a second active layer, a third semiconductor layer, and a third electrode on a second epitaxial substrate;
coupling the second epitaxial structure to the second electrode;
forming a fourth electrode in the second epitaxial structure;
forming a second light-emitting unit by etching the second epitaxial structure;
forming a first dummy stack unit on a lower portion of the second light-emitting unit by etching the first epitaxial structure, and
forming a first light-emitting unit spaced apart from the first dummy stack unit and having a height that is at a same level as a height of the first dummy stack unit.

16. The method of claim 15, wherein the first dummy stack unit has a width that is greater than a width of the second active layer of the second light-emitting unit.

17. The method of claim 15, wherein the first dummy stack unit has a width that is the same as a width of a third electrode layer of the micro light-emitting display apparatus.

18. The method of claim 15, further comprising:
forming a charge blocking layer on the first dummy stack unit, the second light-emitting unit, and the first light-emitting unit,
wherein the forming the charge blocking layer comprises patterning the charge blocking layer such that a partial surface of the third electrode, an upper surface of the fourth electrode, a partial surface of the first electrode, and an upper surface of the second electrode are exposed from the charge blocking layer.

19. The method of claim 15, wherein the coupling the first epitaxial structure to the backplane substrate comprises coupling the first epitaxial structure to the backplane substrate by a first bonding layer.

20. The method of claim 15, further comprising:
forming, after forming the fourth electrode, a third epitaxial structure by stacking in order a sixth semiconductor layer, a third active layer, a fifth semiconductor layer, and a fifth electrode on a third epitaxial substrate;
coupling the third epitaxial structure to the fourth electrode; and
forming a sixth electrode on the third epitaxial structure.
